(19) United States
(12) Patent Application Publication
(10) Pub. No.: US 2025/0351637 A1
(43) Pub. Date: Nov. 13, 2025

(54) METHOD OF MANUFACTURING LIGHT-TRANSMISSIVE MEMBER, LIGHT-TRANSMISSIVE MEMBER, AND LIGHT-EMITTING DEVICE

(71) Applicant: NICHIA CORPORATION, Anan-shi (JP)

(72) Inventor: Takayoshi WAKAKI, Anan-shi (JP)

(73) Assignee: NICHIA CORPORATION, Anan-shi (JP)

(21) Appl. No.: 19/196,283

(22) Filed: May 1, 2025

(30) Foreign Application Priority Data
May 9, 2024 (JP) 2024-076462
Nov. 13, 2024 (JP) 2024-198183

(51) Int. Cl. H10H 29/01; H10H 29/855

(52) U.S. Cl. CPC H10H 29/0363; H10H 29/855; H10H 29/8552

(57) ABSTRACT

A method of manufacturing a light-transmissive member includes: providing a member including: a base having light transmissivity, the base having a first surface, a second surface opposite to the first surface, and a first film disposed on the first surface, the first film containing a substance removable by an acidic substance; and obtaining a light-transmissive second film having voids by bringing the first film into contact with the acidic substance. The first surface of the base includes a first region and a second region adjacent to the first region. A light transmittance of the first region is higher than a light transmittance of the second region. A thickness of the second film located in the second region is less than a thickness of the second film located in the first region.

### CROSS-REFERENCE TO RELATED APPLICATIONS

This application is based on and claims priority to Japanese Patent Application No. 2024-076462, filed on May 9, 2024, and Japanese Patent Application No. 2024-198183, filed on Nov. 13, 2024. The entire contents of these applications are incorporated herein by reference.

### TECHNICAL FIELD

The present disclosure relates to a method of manufacturing a light-transmissive member, a light-transmissive member, and a light-emitting device.

### BACKGROUND

Japanese Patent Publication No. 2010-128258 describes an absorption-type multilayer film neutral density (ND) filter in which a metal absorption film layer has a film thickness distribution, an oxide dielectric film layer has a film thickness distribution opposite to the film thickness distribution of the metal absorption film layer, and the transmittance gradually decreases as the distance from the center of an optical axis increases.

### SUMMARY

An object of one embodiment of the present disclosure is to provide a light-transmissive member having good light extraction, a light-emitting device, and a method of manufacturing a light-transmissive member.

A method of manufacturing a light-transmissive member according to one embodiment of the present disclosure includes: providing a light-transmissive base having a first surface, a second surface opposite to the first surface, and a first film disposed on the first surface, the first film containing a substance removable by an acidic substance; and obtaining a light-transmissive second film having voids by bringing the first film into contact with the acidic substance, wherein the first surface of the base includes a first region and a second region adjacent to the first region, and a thickness of the second film located in the second region is less than a thickness of the second film located in the first region, and a light transmittance of the first region is higher than a light transmittance of the second region.

A light-transmissive member according to one embodiment of the present disclosure includes: a light-transmissive base having a first surface and a second surface opposite to the first surface, and including, on the first surface, a first region and a second region adjacent to the first region; and a light reflection reducing film disposed on the first surface of the base, composed of an inorganic material, and having voids, wherein a thickness of the light reflection reducing film in the second region is less than a thickness of the light reflection reducing film in the first region, and a light transmittance of the first region is higher than a light transmittance of the second region.

A light-emitting device according to one embodiment of the present disclosure includes: the light-transmissive member; and a light source disposed to face the first surface of the light-transmissive member, wherein the light source has a light-emitting surface, and the first region overlaps the light-emitting surface in a top view.

### BRIEF DESCRIPTION OF THE DRAWINGS

FIG. 1 is a schematic top view illustrating an overall configuration of a light-emitting device according to an embodiment;

FIG. 2A is a schematic cross-sectional view taken along line IIA-IIA of FIG. 1;

FIG. 2B is an enlarged view of a region IIB of FIG. 2A;

FIG. 3 is a schematic bottom view illustrating a first example of a light-transmissive member according to the embodiment;

FIG. 4 is a schematic cross-sectional view illustrating a second example of a base of the light-transmissive member according to the embodiment;

FIG. 5 is a schematic cross-sectional view illustrating a third example of the base of the light-transmissive member according to the embodiment;

FIG. 6A is a schematic cross-sectional view illustrating a first film of the light-transmissive member according to the embodiment;

FIG. 6B is a schematic cross-sectional view illustrating a second film of the light-transmissive member according to the embodiment;

FIG. 7 is a schematic top view illustrating a light source included in the light-emitting device according to the embodiment;

FIG. 8 is a schematic cross-sectional view taken along line VIII-VIII of FIG. 7;

FIG. 9A is a diagram illustrating a first region and a second region in a light reflection reducing film of the light-transmissive member according to the embodiment;

FIG. 9B is a diagram illustrating a first example of the thickness of the light reflection reducing film in the first region and the second region of the light-transmissive member according to the embodiment;

FIG. 9C is a diagram illustrating a second example of the thickness of the light reflection reducing film in the first region and the second region of the light-transmissive member according to the embodiment;

FIG. 10 is a flowchart illustrating an overall flow of a method of manufacturing the light-transmissive member according to the embodiment;

FIG. 11 is a flowchart illustrating details of a step of providing a base in FIG. 10;

FIG. 12 is a schematic cross-sectional view illustrating a first example of a support jig;

FIG. 13 is a schematic perspective view of the first example of the support jig as viewed from below;

FIG. 14A is a diagram illustrating the behavior of vapor deposition particles in a vapor deposition method;

FIG. 14B is a diagram illustrating a film formed by the vapor deposition method;

FIG. 15A is a diagram illustrating the behavior of sputtered particles in a sputtering method;

FIG. 15B is a diagram illustrating a film formed by the sputtering method;

FIG. 16 is a schematic bottom view illustrating a second example of the support jig;

FIG. 17 is a schematic bottom view illustrating a third example of the support jig;

FIG. 18 is a schematic bottom view illustrating a fourth example of the support jig;

FIG. 19 is a schematic bottom view illustrating a fifth example of the support jig;

FIG. 20 is a schematic cross-sectional view illustrating a configuration of each of light-transmissive members according to Examples and a Comparative Example; and

FIG. 21 is a diagram illustrating measurement results of the illuminance of light emitted from the light-transmissive members according to Examples and Comparative Example.

### DETAILED DESCRIPTION

A method of manufacturing a light-transmissive member, a light-transmissive member, and a light-emitting device according to embodiments of the present disclosure will be described in detail with reference to the accompanying drawings. The embodiments described below are provided as examples of the method of manufacturing the light-transmissive member, the light-transmissive member, and the light-emitting device that embody technical ideas underlying the present invention, but the present invention is not limited to the described embodiments. In addition, unless otherwise specified, the dimensions, materials, shapes, relative arrangements, and the like of components described in the embodiments are not intended to limit the scope of the present disclosure thereto, but are described as examples. The sizes, positional relationships, and the like, of members illustrated in the drawings may be exaggerated for a better understanding of the structures. Further, in the following description, the same names and reference numerals refer to the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. An X direction along the X-axis and a Y direction along the Y-axis indicate directions along a light-emitting surface of a light-emitting part of the light-emitting device according to an embodiment. A Z direction along the Z axis indicates a direction orthogonal to the light-emitting surface. That is, the light-emitting surface of the light-emitting part is parallel to the XY plane, and the Z-axis is orthogonal to the XY plane.

A direction indicated by an arrow in the X direction is referred to as a +X side, and a direction opposite to the +X side is referred to as a −X side. A direction indicated by an arrow in the Y direction is referred to as a +Y side, and a direction opposite to the +Y side is referred to as a −Y side. A direction indicated by an arrow in the Z direction is referred to as a +Z side, and a direction opposite to the +Z side is referred to as a −Z side. As an example, the light-emitting part of the light-emitting device according to the embodiment is configured to emit light to the +Z side. Further, the phrase “in a top view” as used in the embodiment refers to viewing an object from the light exit surface side of the light-transmissive member according to the embodiment. In the present specification, the phrase “in a top view” may be used to describe, in addition to a portion that can be directly seen from above, a portion that cannot be directly seen from above as if it can be seen from above. The light exit surface of the light-transmissive member according to the embodiment refers to a surface of the light-transmissive member according to the embodiment, through which light emitted from the light source of the light-emitting device according to the embodiment is emitted. However, these expressions do not limit the orientations of the light-transmissive member and the light-emitting device according to the embodiment during use, and the orientations of the light-transmissive member and the light-emitting device according to the embodiment are discretionary.

In the present specification, a surface of the object as viewed from the +Z side is referred to as an “upper surface,” and a surface of the object as viewed from the −Z side is referred to as a “lower surface.” A view of an object from the +Z side is referred to as a top view. A view of an object from the −Z side is referred to as a bottom view. Additionally, the +Z side of the object may be referred to as the upper side, and the −Z side of the object may be referred to as the lower side. In the embodiments described below, each of “along the X-axis,” “along the Y-axis,” and “along the Z-axis” includes a case where the object is at an inclination within a range of ±10° with respect to the corresponding one of the axes. Further, in the embodiments, the term “orthogonal” may include a deviation within ±10° with respect to 90°. The term “disposing” is not limited to a case of direct contact, but also includes a case of indirectly disposing a member via another member, for example.

Further, in the present specification and the claims, if there are multiple components and these components are to be distinguished from one another, the components may be distinguished by adding terms “first,” “second,” and the like before the names of the components. Further, objects to be distinguished may be different between the specification and the claims. Therefore, even if a component recited in the claims is denoted by the same reference numeral as that of a component described in the present specification, an object specified by the component recited in the claims is not necessarily identical with an object specified by the component described in the specification.

For example, if components are distinguished by the ordinal numbers “first,” “second,” and “third” in the specification, and components with “first” and “third” or components with “first” and without a specific ordinal number in the specification are described in the claims, these components may be distinguished by the ordinal numbers “first” and “second” in the claims for ease of understanding. In this case, the components with “first” and “second” in the claims respectively refer to the components with “first” and “third” or the components with “first” and without a specific ordinal number in the specification. This rule is applied not only to components but also other objects in a reasonable and flexible manner.

### Embodiments

### <Configuration of Light-Emitting Device According to Embodiment>

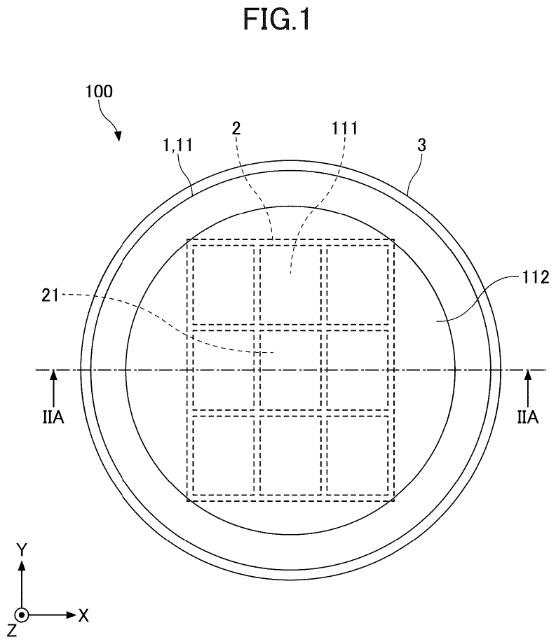

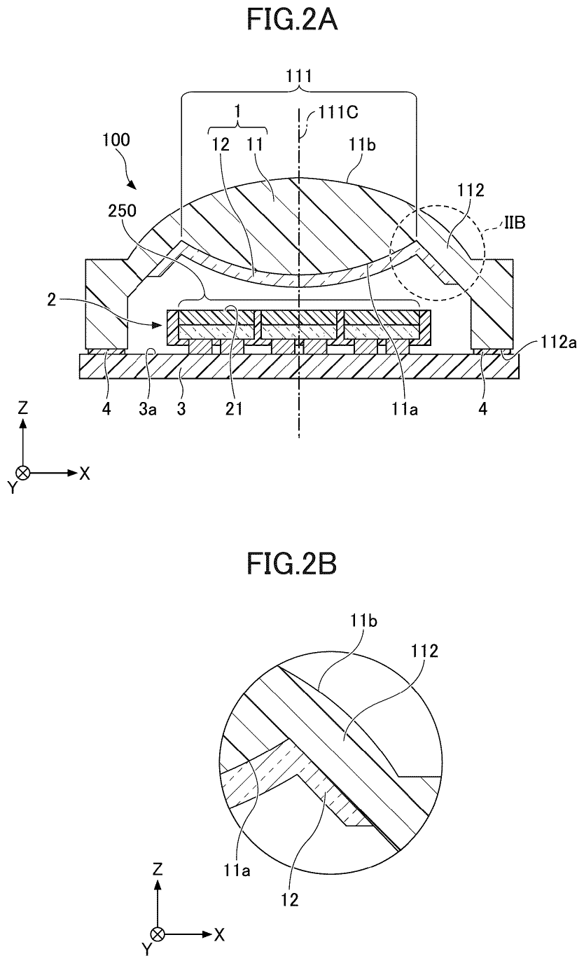

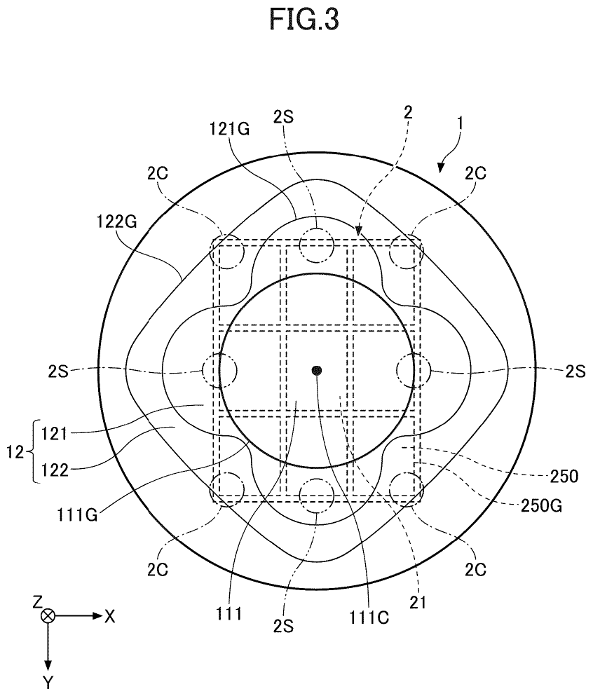

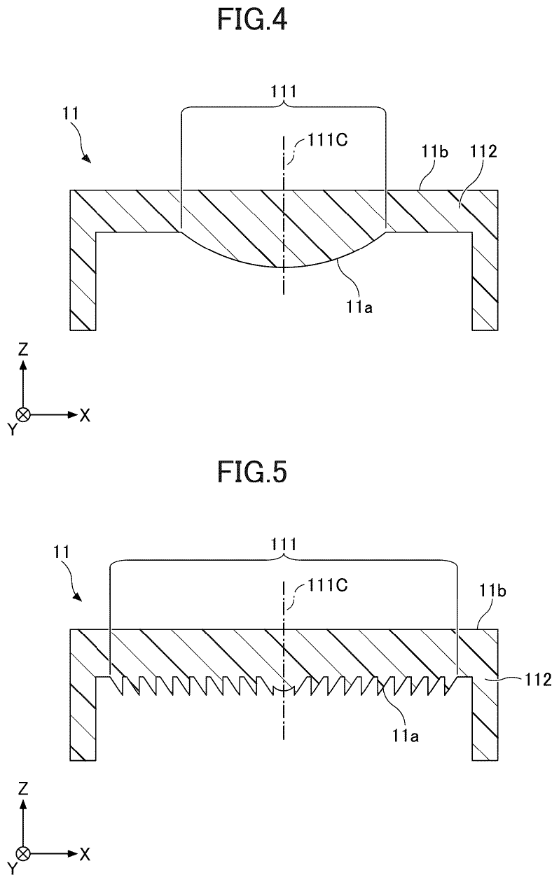

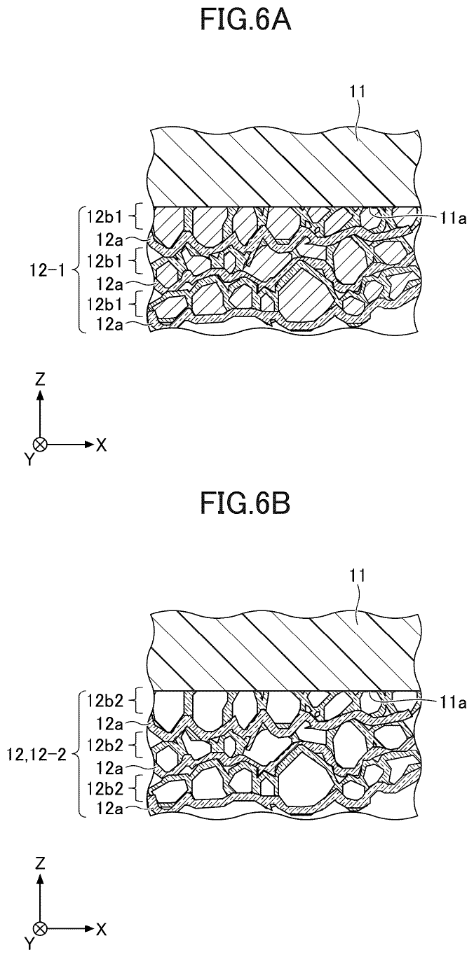

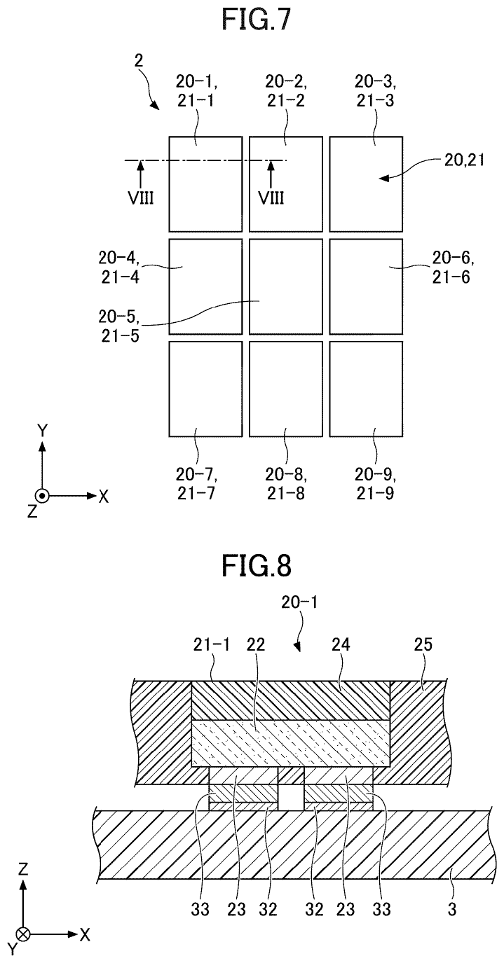

A configuration of a light-emitting device according to an embodiment will be described with reference to FIG. 1, FIG. 2A, FIG. 2B, FIG. 3 to FIG. 5, FIG. 6A, FIG. 6B, FIG. 7, and FIG. 8. FIG. 1 is a schematic top view illustrating an example of an overall configuration of a light-emitting device 100 according to an embodiment. FIG. 2A is a schematic cross-sectional view taken along line IIA-IIA of FIG. 1. FIG. 2B is an enlarged view of a region IIB of FIG. 2A. FIG. 3 is a schematic bottom view illustrating a first example of a light-transmissive member 1 according to the embodiment. FIG. 4 is a schematic cross-sectional view illustrating a second example of a base 11 of the light-transmissive member 1 according to the embodiment. FIG. 5 is a schematic cross-sectional view illustrating a third example of the base 11 of the light-transmissive member 1 according to the embodiment. FIG. 6A is a schematic cross-sectional view illustrating an example of a first film 12-1 of the light-transmissive member 1 according to the embodiment. FIG. 6B is a schematic cross-sectional view illustrating an example of a second film 12-2 of the light-transmissive member 1 according to the embodiment. FIG. 7 is a schematic top view illustrating an example of a light source 2 included in the light-emitting device 100 according to the embodiment. FIG. 8 is a schematic cross-sectional view taken along line VIII-VIII of FIG. 7.

### (Configuration of Light-Emitting Device)

As illustrated in FIG. 1 and FIG. 2A, the light-emitting device 100 includes the light-transmissive member 1 and the light source 2. The light-transmissive member 1 includes a light-transmissive base 11 having a first surface 11a and a second surface 11b opposite to the first surface 11a, and including, on the first surface 11a, a first region 121 and a second region 122 adjacent to the first region 121. The light-transmissive member 1 includes a light reflection reducing film 12 composed of an inorganic material, and having voids. The light reflection reducing film 12 is disposed on the first surface 11a of the base 11. The light source 2 is disposed to face the first surface 11a of the light-transmissive member 1, and has a light-emitting surface 21.

In the example illustrated in FIG. 1 and FIG. 2A, the light-emitting device 100 includes a substrate 3 on which the light-transmissive member 1 and the light source 2 are disposed, and an adhesive member 4 that bonds the light-transmissive member 1 and the substrate 3. The base 11 of the light-transmissive member 1 includes a lens 111 and a support 112 that supports the lens 111. The base 11 is disposed on an upper surface 3a of the substrate 3 via the adhesive member 4 such that a lower surface 112a of the support 112 and the upper surface 3a of the substrate 3 face each other.

The light source 2 is disposed on the upper surface 3a of the substrate 3. The light source 2 illustrated in FIG. 1, FIG. 2A, FIG. 2B, and FIG. 3 includes nine light-emitting surfaces 21 each having a substantially rectangular shape. The nine light-emitting surfaces 21 are arranged in a matrix of three rows and three columns on an imaginary plane (for example, the XY plane). In the example illustrated in FIG. 3, a light emission region 250 includes the nine light-emitting surfaces 21. The shape of a light emission region outer perimeter 250G is a substantially rectangular shape in a top view. The light source 2 emits light from the nine light-emitting surfaces 21 toward the lens 111 of the light-transmissive member 1. The number of the light-emitting surfaces 21 included in the light source 2 is not limited to nine, and may be at least one. The light emission region 250 includes at least one light-emitting surface 21.

In the example illustrated in FIG. 1, the outer shape of the light-emitting device 100 in a top view is a substantially circular shape. However, the outer shape of the light-emitting device 100 in a top view may be a substantially rectangular shape, a substantially elliptical shape, a substantially polygonal shape, or the like.

In the example illustrated in FIG. 3, the outer shape of the light source 2 in a top view is a substantially rectangular shape. The center of the light source 2 and an optical axis 111C of the lens 111 coincide with each other in a top view. A lens outer perimeter 111G is an outer perimeter of the lens 111. The light emission region outer perimeter 250G is an outer perimeter of the light emission region 250 of the light source 2 including all of the light-emitting surfaces 21. In the present embodiment, the light emission region outer perimeter 250G is an outer perimeter of the light emission region 250 including all of the nine light-emitting surfaces 21. A first region outer perimeter 121G is an outer perimeter of the first region 121 of the light reflection reducing film 12. A second region outer perimeter 122G is an outer perimeter of the second region 122 of the light reflection reducing film 12. In FIG. 3, the light source 2 indicated by a dashed line is superimposed on the bottom view of the light-transmissive member 1 to indicate the positional relationship among the light-transmissive member 1, the light source 2, and the light reflection reducing film 12.

The light source 2 may cause the nine light-emitting surfaces 21 to be illuminated individually or in groups. The light-emitting device 100 can increase the contrast on an irradiation surface irradiated with light from the light source 2 by causing the nine light-emitting surfaces 21 to be illuminated individually or to be illuminated in groups, with desired brightness. The light-emitting device 100 can perform partial irradiation on the irradiation surface by causing the nine light-emitting surfaces 21 to be illuminated individually or to be illuminated in groups. The “partial irradiation” means that a portion of the irradiation surface is irradiated with light.

In a case where the light-emitting device 100 is used as a flash light source when an imaging device captures an image, the light-emitting device 100 can emit light by switching between a wide-angle mode and a narrow-angle mode. The wide-angle mode is an operation mode of the light-emitting device 100 in which light is emitted from all of the light-emitting surfaces 21. The narrow-angle mode is an operation mode of the light-emitting device 100 in which light is emitted from only light-emitting surfaces 21 located at and near the center of the light emission region 250 and light is not emitted from light-emitting surfaces 21 located near the light emission region outer perimeter 250G. In the narrow-angle mode, the light distribution angle is narrower than that in the wide-angle mode. In the light-emitting device 100, irradiation light can be switched in accordance with the wide-angle mode or the narrow-angle mode. For example, by utilizing the light emitted from the light-emitting device 100, the imaging device can capture images in accordance with various photographing modes such as close-up photography or telephoto photography.

The light-emitting device 100 does not have to include the one light-transmissive member 1 and the one lens 111 illustrated in FIG. 1 and FIG. 2A, and may include two or more light-transmissive members, two or more lenses arranged along the optical axis 111C, or both.

In the light-transmissive member 1 according to the present embodiment, the light reflection reducing film 12 is a light-transmissive film composed of an inorganic material and having voids. As illustrated in FIG. 6B, the light reflection reducing film 12 is a thin film having a refractive index lower than the square root of the refractive index of the base 11, which is an object on which a film is to be formed, by containing air having a refractive index of 1.0 in the light reflection reducing film 12.

The light reflection reducing film 12 is an optical thin film having a large number of voids, containing silicon dioxide (SiO₂) as a framework, and having a refractive index of 1.300 or less. In the present embodiment, the light reflection reducing film 12 having a refractive index between the refractive index of the base 11 and the refractive index of air is disposed between the base 11 and air so as to reduce a refractive index between the base 11 and air. As a result, the possibility that light from the light source 2 is reflected by the first surface 11a of the base 11 can be reduced. Accordingly, the light extraction of the light-transmissive member 1 can be improved.

As illustrated in FIG. 2A and FIG. 2B, in the light-transmissive member 1 of the light-emitting device 100 according to the present embodiment, the thickness of the light reflection reducing film 12 in the second region 122 is less than the thickness of the light reflection reducing film 12 in the first region 121, and the light transmittance of the first region 121 is higher than the light transmittance of the second region 122. Because the thickness of the light reflection reducing film 12 in the second region 122 is less than the thickness of the light reflection reducing film 12 in the first region 121, the light transmittance of the first region 121 is higher than the light transmittance of the second region 122. Because the light transmittance of the first region 121 is higher than the light transmittance of the second region 122, the light extraction efficiency in the first region 121 is higher than the light extraction efficiency in the second region 122. Accordingly, in the present embodiment, the light-transmissive member 1 having good light extraction can be provided. In FIG. 2B, the thickness of the light reflection reducing film 12 in the first region 121 and the thickness of the light reflection reducing film 12 in the second region 122 are exaggerated for ease of understanding.

As illustrated in FIG. 3, in the light-emitting device 100, the first region 121 of the light-transmissive member 1 overlaps the light-emitting surfaces 21 in a top view. In the present embodiment, the first region 121 of the light-transmissive member 1 overlaps the light-emitting surfaces 21 except for corner portions 2C of the light emission region outer perimeter 250G having a substantially rectangular shape in a top view. From another viewpoint, the first region outer perimeter 121G has eight intersections with the light emission region outer perimeter 250G. With this configuration, the amount of light emitted from the light source 2 and passing through the second region 122 of the light-transmissive member 1 is less than the amount of light passing through the first region 121. The position of each of the corner portions 2C of the light emission region outer perimeter 250G is farther from the optical axis 111C of the lens 111 than the position of each of sides 2S of the light emission region outer perimeter 250G is. In the present embodiment, the corner portions 2C of the light emission region outer perimeter 250G overlaps the support 112 in a top view. In the light-emitting device 100, light emitted from the vicinity of the corner portions 2C of the light emission region outer perimeter 250G and traveling toward the support 112 without entering the first surface 11a of the lens 111 is likely to become stray light. However, in the light-emitting device 100 to which the light-transmissive member 1 is applied, the amount of light passing through the second region 122 is small, and thus the occurrence of stray light in the second region 122 of the light-transmissive member 1 can be reduced.

In the light-emitting device 100 illustrated in FIG. 3, the light source 2 having a substantially rectangular outer shape in a top view is disposed such that the four corner portions 2C of the light source 2, where stray light is likely to be generated, overlap the second region 122 and also the four sides 2S of the light source 2 overlap the first region 121. The light transmittance of the light reflection reducing film 12 in the second region 122 is lower than the light transmittance of the light reflection reducing film 12 in the first region 121. Therefore, the amount of light emitted from the four corner portions 2C and transmitted through the light reflection reducing film 12 located in the second region 122 is less than the amount of light emitted from the four sides 2S and transmitted through the light reflection reducing film 12 located in the first region 121. This can reduce stray light and allows a large amount of light from the four sides 2S to be transmitted through the first region 121, thereby allowing a greater amount of light to be extracted.

The first region 121 illustrated in FIG. 3 is located at a position overlapping the optical axis 111C of the lens 111 in a top view. Thus, for example, when the operation mode of the light-emitting device 100 is the narrow-angle mode, light emitted from the light source 2 is easily transmitted through the first region 121 of the light-transmissive member 1. Therefore, by utilizing the light-emitting device 100, irradiation light corresponding to a photographing mode such as telephoto photography that requires a greater amount of light can be obtained.

Each component of the light-emitting device 100 will be described in detail below.

### (Light-Transmissive Member 1)

The light-transmissive member 1 is a member configured to transmit light from the light source 2, and includes the base 11 and the light reflection reducing film 12. The light-transmissive member 1 is disposed so as to cover the light source 2. In the example illustrated in FIG. 1, the light-transmissive member 1 has a substantially circular shape in a top view. However, the shape of the light-transmissive member 1 in a top view may be a substantially elliptical shape, a substantially rectangular shape, a substantially polygonal shape, or the like.

The base 11 of the light-transmissive member 1 has light transmissivity with respect to light emitted from the light source 2, and includes at least one of a resin material, such as a polycarbonate resin, an acrylic resin, a silicone resin, or an epoxy resin, or a glass material. In the example illustrated in FIG. 1, the outer shape of the base 11 in a top view is a substantially circular shape.

In the example illustrated in FIG. 2A, the lens 111 of the base 11 is a biconvex lens. The lens 111 is a biconvex lens having the first surface 11a and the second surface 11b, both of which are convex surfaces. However, the lens 111 is not limited to a biconvex lens, and may be a plano-convex lens, a biconcave lens, a plano-concave lens, a Fresnel lens, an array lens, a meniscus lens, an aspherical lens, a cylindrical lens, or the like.

For example, in the second example of the base 11 illustrated in FIG. 4, the lens 111 is a plano-convex lens having the first surface 11a on the −Z side on which the light source 2 is located, and the first surface 11a is a convex surface. In the third example of the base 11 illustrated in FIG. 5, the lens 111 is a Fresnel lens having the first surface 11a on the −Z side on which the light source 2 is located, and the first surface 11a includes a plurality of concentrically arranged projections. Each of FIG. 4 and FIG. 5 illustrates a cross section including the optical axis 111C of the lens 111 included in the base 11.

In the example illustrated in FIG. 1, the lens 111 has a substantially circular shape in a top view. However, the lens 111 may have a substantially rectangular shape, a substantially elliptical shape, a substantially polygonal shape, or the like in a top view. Further, the lens 111 may have a rotationally symmetric shape in a top view. Considering that an imaging range of a general imaging device is substantially rectangular, it is preferable that the shape of the lens 111 in a top view has four-fold rotationally symmetric shape or a two-fold rotationally symmetric shape. In the lens 111, the radii of curvature of the first surface 11a and the second surface 11b, the magnitude relationship between the radii of curvature, the thickness of the lens, and the like can also be appropriately changed.

The support 112 of the base 11 supports the lens 111 such that the lens 111 is disposed above the light source 2. In the example illustrated in FIG. 1 and FIG. 2A, the lens 111 and the support 112 are an integrated member without using an adhesive member. However, the lens 111 and the support 112 may be separate members bonded to each other by an adhesive member.

As will be described later, the light reflection reducing film 12 of the light-transmissive member 1 is an optical thin film having voids, containing silicon dioxide (SiO₂) as a framework, and having a refractive index of 1.300 or less. The voids are formed by eluting indium oxide (I)(In₂O) and indium (In) from a vapor deposition film (first film 12-1) containing silicon dioxide (SiO₂), indium oxide (I)(In₂O), and indium (In). The light reflection reducing film 12 has a refractive index of preferably 1.250 or less, more preferably 1.200 or less, even more preferably 1.170 or less. Indium oxide (I)(In₂O) and indium (In) contained in the first film 12-1 are eluted to form a large number of voids, and silicon dioxide (SiO₂) not being eluted remains to serve a framework, thereby obtaining the light reflection reducing film 12. The light reflection reducing film 12 may contain an extremely trace amount of indium oxide (III)(In₂O₃) in addition to silicon dioxide (SiO₂). The content of indium oxide (III)(In₂O₃) in the light reflection reducing film 12 may be set such that the refractive index of the second film 12-2 is decreased by about 0.01 after bringing the first film 12-1 treated with an acidic solution in contact with a strong acidic solution of pH 2.0 or less.

Because the refractive index of the light reflection reducing film 12 is 1.300 or less, a reflection reducing effect can be enhanced throughout the entire visible region. The refractive index of the optical thin film can be obtained as follows. A reflection spectrum is measured by a spectrometer, a minimum value of a reflected light intensity is measured as a reflectance when incident light intensity is taken as 100, and then the refractive index of the optical thin film is calculated from the measured minimum value of the reflectance by using Fresnel coefficients.

In the present embodiment, because the base 11 including the lens 111 is used as the object on which the light reflection reducing film 12 is to be formed, a reflectance R′ obtained by the measurement includes multiple repeated reflections including back surface reflection. Because the measured reflectance R′ includes the multiple repeated reflections, a reflectance R of the thin film can be represented by the following formula (1).

$$[ Formula 1 ]$$

$${R}^{′} = \frac{{R}_{0} + R - 2 {R}_{0} R}{1 - {R}_{0} R} \qquad ( 1 )$$

In the formula (1), Ro represents a reflectance of the base 11 (object on which the film is to be formed). The reflectance R of the light reflection reducing film 12 can be calculated from the actually measured reflectance R′ of the light reflection reducing film 12 based on the formula (1). The reflectance R of the thin film is a reflectance without considering reflection from the back surface. When Fresnel coefficients are used, the reflectance R of the light reflection reducing film 12 can be calculated from a refractive index nm of the base 11 (object on which the film is to be formed) and a refractive index n of the light reflection reducing film 12, and can be represented by the following formula (2).

$$[ Formula 2 ]$$

$$R = \frac{{( {n}^{2} - {n}_{m} )}^{2}}{{( {n}^{2} + {n}_{m} )}^{2}} \qquad ( 2 )$$

When a refractive index in the air is approximated to 1 and the refractive index n of the light reflection reducing film 12 is higher than the square root of the refractive index nm of the base 11, the refractive index n of the light reflection reducing film 12 can be represented by the following formula (3).

$$[ Formula 3 ]$$

$$n = {\{ \frac{{n}_{m} ( 1 + \sqrt{R} )}{1 - \sqrt{R}} \}}^{\frac{1}{2}} when n > \sqrt{{n}_{m}} \qquad ( 3 )$$

When the refractive index n of the light reflection reducing film 12 is lower than the square root of the refractive index nm of the base 11, the refractive index n of the light reflection reducing film 12 (thin film) can be represented by the following formula (4).

$$[ Formula 4 ]$$

$$n = {\{ \frac{{n}_{m} ( 1 - \sqrt{R} )}{1 + \sqrt{R}} \}}^{\frac{1}{2}} when n > \sqrt{{n}_{m}} \qquad ( 4 )$$

The refractive index of the light reflection reducing film 12 can be calculated based on the formulae (1) to (4). With respect to the refractive index n of the light reflection reducing film 12, the document “Basic Theory of Optical Thin Film-Fresnel Coefficient and Characteristic Matrix-” written by Mitsunobu Kobiyama and published by Optronics Co., Ltd., on Feb. 25, 2011 (enlarged and revised edition-first copy) can be referred to.

The light reflection reducing film 12 has a porosity in a range of 30% or more and 90% or less. By setting the porosity of the light reflection reducing film 12 to 30% or more, the refractive index of the light reflection reducing film 12 can be reduced. By setting the porosity of the light reflection reducing film 12 to 90% or less, the strength of the light reflection reducing film 12 formed on the base 11 can be maintained and also the refractive index of the light reflection reducing film 12 can be reduced. The porosity of the light reflection reducing film 12 is more preferably in a range of 40% or more and 90% or less, even more preferably in a range of 50% or more and 90% or less, and yet even more preferably in a range of 60% or more and 85% or less. The porosity (total porosity Vp) of the optical thin film can be determined by using a Lorentz-Lorenz equation as shown in the following formula (5). In the following formula (5), n_{f} represents an observed refractive index of the light reflection reducing film 12, and n_{b} represents a refractive index of the framework of the light reflection reducing film 12. The refractive index n_{f} of the light reflection reducing film 12 is the refractive index of the light reflection reducing film 12 having voids obtained based on the formulae (1) to (4). The refractive index n_{b} of the framework of the light reflection reducing film 12 is obtained by using a refractive index (1.460) of silicon dioxide (SiO₂), because the framework of the light reflection reducing film 12 is mainly composed of silicon dioxide (SiO₂).

$$[ Formula 5 ]$$

$$Vp = 1 - \frac{( {n}_{f}^{2} - 1 )}{( {n}_{f}^{2} + 2 )} {( \frac{( {n}_{b}^{2} - 1 )}{( {n}_{b}^{2} + 2 )} )}^{- 1} \qquad ( 5 )$$

The light reflection reducing film 12 is disposed on the first surface 11a of the base 11 and in the first region 121 and the second region 122 adjacent to the first region 121. The thickness of the light reflection reducing film 12 in the first region 121 is 500 Å or more and 2,200 Å or less. The thickness of the light reflection reducing film 12 in the second region 122 is greater than 0 Å and less than 2,000 Å. In the present embodiment, “the thickness of the light reflection reducing film 12 in the second region 122 is less than the thickness of the light reflection reducing film 12 in the first region 121” means that the maximum thickness of the light reflection reducing film 12 in the second region 122 is less than the maximum thickness of the light reflection reducing film 12 in the first region 121. In the present embodiment, the first region 121 is a region that is located at the center of the lens 111 (so as to overlap the optical axis 111C) in a top view and in which a difference between the thickness of the light reflection reducing film 12 and the maximum thickness of the light reflection reducing film 12 is less than 10%. For example, when the optical axis 111C is defined as being on the inner side, the second region 122 is a region located outward of the first region 121. The boundary between the first region 121 and the second region 122 may be a position that is closest to the first region 121 and at which a difference between the thickness of the light reflection reducing film 12 in the second region 122 and the maximum thickness of the light reflection reducing film 12 is 10%. As long as there is a boundary between the first region 121 and the second region 122, even if the light reflection reducing film 12 in the second region 122 locally has a portion having a thickness close to the maximum thickness of the light reflection reducing film 12 in the first region 121, the portion is regarded as being included in the second region 122 if the thickness of the portion is less than the maximum thickness of the light reflection reducing film 12 in the first region 121.

### (Light Source 2)

As illustrated in FIG. 7, the light source 2 includes nine light-emitting parts 20 including the respective light-emitting surfaces 21. The nine light-emitting parts 20 are configured to emit light from the respective light-emitting surfaces 21 toward the lens 111 of the light-transmissive member 1 provided above the light source 2. The light-emitting surfaces 21 refer to main light extraction surfaces of the light-emitting parts 20.

The nine light-emitting parts 20 include light-emitting parts 20-1, 20-2, 20-3, 20-4, 20-5, 20-6, 20-7, 20-8, and 20-9. The nine light-emitting parts 20 are arranged in the lengthwise direction or the widthwise direction or in a matrix in a top view. From another viewpoint, the nine light-emitting parts 20 are arranged along the X direction. Alternatively, the nine light-emitting parts 20 are arranged along the X direction and the Y direction orthogonal to the X direction. The nine light-emitting parts 20 are arranged along the X direction and the Y direction.

The light-emitting part 20-1 has a light-emitting surface 21-1. The light-emitting part 20-2 has a light-emitting surface 21-2. The light-emitting part 20-3 has a light-emitting surface 21-3. The light-emitting part 20-4 has a light-emitting surface 21-4. The light-emitting part 20-5 has a light-emitting surface 21-5. The light-emitting part 20-6 has a light-emitting surface 21-6. The light-emitting part 20-7 has a light-emitting surface 21-7. The light-emitting part 20-8 has a light-emitting surface 21-8. The light-emitting part 20-9 has a light-emitting surface 21-9. It is preferable that 80% or more of the nine light-emitting surfaces 21 are disposed inward of the lens 111 (inward relative to the contour of the lens 111) in a top view. With this configuration, light emitted from the light-emitting surfaces 21 can be efficiently incident on the lens 111 and good optical characteristics can be obtained. The light-emitting parts 20 respectively overlap the light-emitting surfaces 21 in a top view. Thus, in the example illustrated FIG. 7, the reference numeral of each of the light-emitting parts 20 is illustrated together with the reference numeral of a corresponding light-emitting surface 21. In the following description, if two or more components substantially coincide with each other or overlap each other, reference numerals may be illustrated together. The shape of each of the nine light-emitting surfaces 21 in a top view is a substantially rectangular shape. However, the shape of each of the nine light-emitting surfaces 21 in a top view may be a substantially circular shape, a substantially elliptical shape, or may be a polygonal shape such as a substantially triangular shape or a substantially hexagonal shape.

Each of the light-emitting parts 20 includes a light-emitting element 22, a wavelength conversion member 24 disposed on the light-emitting element 22, and a covering member 25 covering the side surfaces of the light-emitting element 22 and the side surfaces of the wavelength conversion member 24.

The light-emitting parts 20 each including the light-emitting element 22 and the wavelength conversion member 24 can emit mixed-color light in which a color of light emitted from the light-emitting element 22 and a color of light emitted from the wavelength conversion member 24 are mixed. The degree of freedom in the color of light emitted from each of the light-emitting parts 20 can be increased by the combination of the light-emitting element 22 and the wavelength conversion member 24.

The light source 2 includes the plurality of light-emitting parts 20, and the covering member 25 integrally holds a plurality of light-emitting elements 22 and a plurality of wavelength conversion members 24. In the example illustrated in FIG. 7, the covering member 25 is disposed between adjacent light-emitting elements 22 and between adjacent wavelength conversion members 24. In this manner, the covering member 25 integrally holds nine light-emitting elements 22 included in the nine light-emitting parts 20 and nine wavelength conversion members 24 included in the nine light-emitting parts 20. The light source 2 including the covering member 25 can reduce light leaking from the side surfaces of the light-emitting parts 20 and the side surfaces of the wavelength conversion members 24, and thus the light extraction efficiency of the light-emitting parts 20 can be improved.

Because the light source 2 includes the plurality of light-emitting parts 20, the amount of light that can be emitted from the light source 2 can be increased. Further, the covering member 25 integrally holds the plurality of light-emitting elements 22 and the plurality of wavelength conversion members 24, and thus the light source 2 can be easily mounted.

The light source 2 will be described in detail. In the example illustrated in FIG. 8, the light-emitting part 20-1 is disposed on the surface on the +Z side of the substrate 3, with the upper surface of the light-emitting part 20-1 serving as the light-emitting surface 21-1 and the surface opposite the light-emitting surface 21-1 serving as a mounting surface. A wavelength conversion member 24 is provided on the surface on the +Z side of a light-emitting element 22. The covering member 25 covers the side surfaces of the light-emitting element 22 and the side surfaces of the wavelength conversion member 24 except for the upper surface of the wavelength conversion member 24. Light-emitting surfaces 21 of adjacent light-emitting parts 20 of the nine light-emitting parts 20 included in the light source 2 are separated from each other by the covering member 25. The adjacent light-emitting surfaces 21 may be continuous with each other. For example, one wavelength conversion member 24 may cover the entirety of the upper surfaces of a plurality of light-emitting elements 22.

At least one pair of positive and negative electrodes 23 are provided on the surface of the light-emitting element 22 opposite the light-emitting surface 21-1.

The light-emitting element 22 includes various semiconductors such as group III-V compound semiconductors and group II-VI compound semiconductors. As the semiconductors, nitride-based semiconductors such as In_{X}Al_{Y}Ga_{1-X-Y}N (0≤X, 0≤Y, X+Y≤1) are preferably used, and InN, AlN, GaN, InGaN, AlGaN, InGaAlN, and the like can also be used. The light-emitting element 22 is, for example, a light emitting diode (LED) or a laser diode (LD). The peak emission wavelength of the light-emitting element 22 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance included in the wavelength conversion member 24, and the like.

The wavelength conversion member 24 is a member having, for example, a substantially rectangular shape in a top view. The wavelength conversion member 24 is disposed so as to cover the upper surface of the light-emitting element 22. The wavelength conversion member 24 includes a wavelength conversion substance that converts a wavelength of at least a portion of light from the light-emitting element 22. The wavelength conversion member 24 can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin or a modified resin thereof having high light resistance and heat resistance is preferable. As used herein, the term “light-transmissive” means that 60% or more of the light from the light-emitting element 22 is preferably transmitted. Further, a thermoplastic resin such as a polycarbonate resin, an acrylic resin, a methylpentene resin, or a polynorbornene resin can be used for the wavelength conversion member 24. Further, the wavelength conversion member 24 may include a light diffusing substance. For example, the wavelength conversion member 24 may be a resin material, a ceramic, glass, or the like containing a wavelength conversion substance, a sintered body of a wavelength conversion substance, or the like. Further, the wavelength conversion member 24 may be a multilayer member in which a resin layer is disposed on the surface on the +Z side of a formed body of a resin, a ceramic, glass, or the like.

Examples of a wavelength conversion substance included in the wavelength conversion member 24 include yttrium aluminum garnet based phosphors (for example, (Y, Gd)₃(Al, Ga)₅O₁₂:Ce), lutetium aluminum garnet based phosphors (for example, Lu₃(Al, Ga)₅O₁₂:Ce), terbium aluminum garnet based phosphors (for example, Tb₃(Al, Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba, Sr, Ca, Mg)₂SiO₄:Eu), oxynitride based phosphors such as β-SiAlON based phosphors (for example, (Si, Al)₃(O, N)₄:Eu) and α-SiAlON based phosphors (for example, Ca(Si, Al)₁₂(O, N)₁₆:Eu), nitride based phosphors such as LSN based phosphors (for example, (La, Y)₃Si₆N₁₁:Ce), BSESN based phosphors (for example, (Ba, Sr)₂Si₅Ng:Eu), SLA based phosphors (for example, SrLiAl₃N₄:Eu), CASN based phosphors (for example, CaAlSiN₃:Eu), and SCASN based phosphors (for example, (Sr, Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs, FA, MA)(Pb, Sn)(F, Cl, Br, I)₃, where FA and MA represent formamidinium and methylammonium, respectively), II-VI quantum dots (for example, CdSe), III-V quantum dots (for example, InP), and quantum dots having a chalcopyrite structure (for example, (Ag, Cu)(In, Ga)(S, Se)₂). The wavelength conversion substances described above are particles. One of these wavelength conversion substances may be used alone, or two or more of these wavelength conversion substances may be used in combination.

In the present embodiment, the light source 2 uses a blue LED as the light-emitting element 22. The wavelength conversion member 24 includes a wavelength conversion substance that converts the wavelength of light emitted from the light-emitting element 22 into the wavelength of yellow light. Accordingly, the light source 2 can emit white light. The wavelength or the chromaticity of light emitted from the light source 2 may be appropriately selected according to the application of the light-emitting device 100. The wavelength conversion member 24 includes a light diffusing substance. As the light diffusing substance, titanium oxide, barium titanate, aluminum oxide, silicon oxide, or the like can be used.

The covering member 25 is a member covering the side surfaces of the light-emitting element 22 and the side surfaces of the wavelength conversion member 24. The covering member 25 directly or indirectly covers the side surfaces of the light-emitting element 22 and the side surfaces of the wavelength conversion member 24. The upper surface of the wavelength conversion member 24 is exposed through the covering member 25, and is the light-emitting surface 21-1 of the light-emitting part 20-1. The covering member 25 may be separated between adjacent light emitting parts of the nine light-emitting parts 20. To improve the light extraction efficiency, the covering member 25 is preferably formed of a member having a high light reflectance. For example, an organic material such as a resin containing a light reflective substance such as a white pigment can be used for the covering member 25. For example, the covering member 25 may be a light reflective member formed of an inorganic material including boron nitride or alkali metal silicate. In this case, the covering member 25 may further include titanium oxide or zirconium oxide.

Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of the above substances alone or a combination of two or more of the above substances. Further, as the resin material, it is preferable to use a base material including a resin material whose main component is a thermosetting resin such as an epoxy resin, an epoxy-modified resin, a silicone resin, a silicone-modified resin, or a phenol resin. The covering member 25 may be configured with a member having light transmissivity or light absorbability with respect to visible light as necessary. A member having light absorbability contains, for example, carbon black.

The light-emitting part 20 is electrically connected to wiring 32 of the substrate 3. The substrate 3 preferably includes the wiring 32 on the surface of the substrate 3. The substrate 3 may include the wiring 32 inside the substrate 3. The light-emitting part 20 and the substrate 3 are electrically connected to each other by connecting the wiring 32 of the substrate 3 to at least the pair of positive and negative electrodes 23 of the light-emitting element 22 via electrically-conductive members 33. The configuration, the size, and the like of the wiring 32 of the substrate 3 are set in accordance with the configuration, the size, and the like of the electrodes 23 of the light-emitting element 22.

The wiring 32 can be composed of at least one of copper, iron, nickel, tungsten, chromium, aluminum, silver, gold, titanium, palladium, rhodium, or an alloy thereof. In addition, a layer of silver, platinum, aluminum, rhodium, gold, an alloy thereof, or the like may be provided on the surface layer of the wiring 32 from the viewpoint of wettability of the electrically-conductive members 33 and light reflectivity of the wiring 32, or the like.

### (Substrate 3)

The substrate 3 is a plate-shaped member having a substantially circular shape in a top view. The substrate 3 includes wiring on which various electronic components such as the light source 2 can be mounted. The shape of the substrate 3 in a top view may be a substantially rectangular shape, a substantially elliptical shape, a substantially polygonal shape, or the like.

As a base material of the substrate 3, an insulating material is preferably used, and also a material that does not easily transmit light emitted from the light-emitting surfaces 21, external light, or the like is preferably used. Further, as the base material of the substrate 3, a material having a certain strength is preferably used. Specifically, as the base material of the substrate 3, a ceramic such as alumina, aluminum nitride, mullite, or silicon nitride, or a resin such as a phenol resin, an epoxy resin, a polyimide resin, a bismaleimide-triazine resin (BT resin), polyphthalamide, or a polyester resin can be used.

### (Thickness of Light Reflection Reducing Film 12)

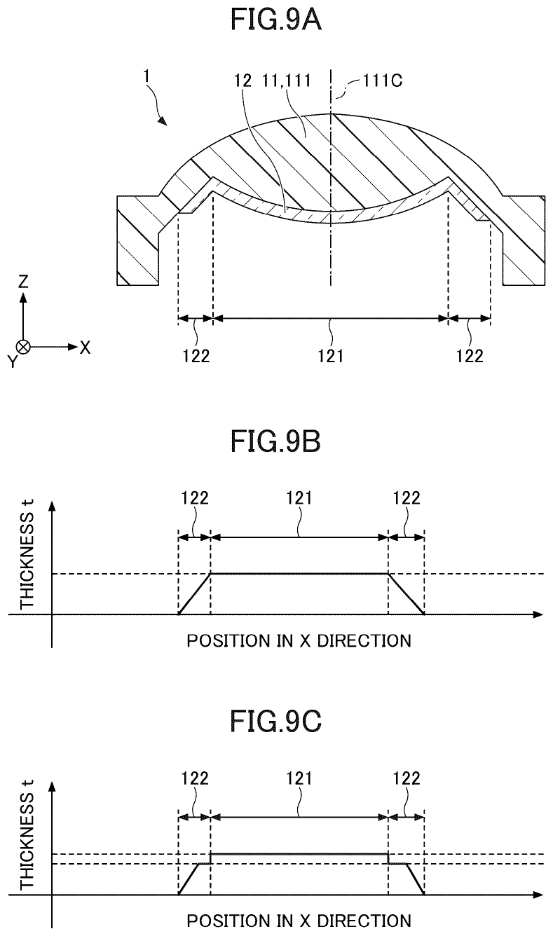

Next, the thickness of the light reflection reducing film 12 of the light-transmissive member 1 according to the embodiment will be described with reference to FIG. 9A, FIG. 9B, and FIG. 9C. FIG. 9A is a diagram illustrating an example of the first region 121 and the second region 122 in the light reflection reducing film 12 of the light-transmissive member 1 according to the embodiment. FIG. 9B is a diagram illustrating a first example of the thickness of the light reflection reducing film 12 in the first region 121 and the second region 122 of the light-transmissive member 1 according to the embodiment. FIG. 9C is a diagram illustrating a second example of the thickness of the light reflection reducing film 12 in the first region 121 and the second region 122 of the light-transmissive member 1 according to the embodiment. A position in the X direction on the horizontal axis of each of FIG. 9B and FIG. 9C corresponds to a position in the X direction of FIG. 9A. In the present embodiment, the thickness of the light reflection reducing film 12 is defined as a thickness t. For the sake of description, the thickness of the light reflection reducing film 12 in the first region 121 may be referred to as a thickness t1, and the thickness of the light reflection reducing film 12 in the second region 122 may be referred to as a thickness t2.

FIG. 9A illustrates a cross section including the optical axis 111C of the lens 111 (base 11). In the example illustrated in FIG. 9A, the second region 122 is located adjacent to both sides of the first region 121 in the X direction. In the first example illustrated in FIG. 9B, the thickness t2 of the light reflection reducing film 12 in the second region 122 continuously decreases in a direction from the first region 121 toward the second region 122. Conversely, in the second example illustrated in FIG. 9C, the thickness t2 of the light reflection reducing film 12 in the second region 122 decreases stepwise in a direction from the first region 121 toward the second region 122.

In the second region 122, the thickness t of the light reflection reducing film 12 decreases continuously or stepwise, and thus an effect of reducing light reflection by the light reflection reducing film 12 decreases according to the thickness t. As a result, the light transmittance of the second region 122 decreases according to the thickness t. That is, in the light-transmissive member 1, the light transmittance decreases continuously or stepwise in a direction from the first region 121 toward the second region. Because the light transmittance of the first region 121 is higher than the light transmittance of the second region 122, light extraction can be improved. Further, because the light transmittance decreases continuously or stepwise in a direction from the first region 121 toward the second region, the occurrence of stray light, which becomes more pronounced in a direction from the first region 121 toward the second region 122, can be reduced.

In the example illustrated in FIG. 9A, the difference between the thickness t1 of the light reflection reducing film 12 in the first region 121 and the thickness t2 of the light reflection reducing film 12 in the second region 122 is 5% or more of the thickness t1 of the light reflection reducing film 12 in the first region 121. Accordingly, the amount of light emitted from the light source 2 and passing through the second region 122 of the light-transmissive member 1 is reduced by 5% or more as compared to the amount of light passing through the first region 121, and thus the occurrence of stray light in the second region 122 can be reduced. From the viewpoint of reducing stray light, the above-described difference in thickness is more preferably 20% or more of the thickness t of the light reflection reducing film 12 in the first region 121.

In the example illustrated in FIG. 9A, the maximum thickness of the light reflection reducing film 12 in the first region 121 is 500 Å or more and 2,000 Å or less. With this configuration, the amount of light emitted from the light source 2 and passing through the first region 121 of the light-transmissive member 1 can be increased, and the light extraction of the light-transmissive member 1 can be improved.

In the light-transmissive member 1 according to the present embodiment, a light-transmissive base film having a refractive index lower than the refractive index of the base 11 and higher than the refractive index of the light reflection reducing film 12 is disposed between the base 11 and the light reflection reducing film 12. By forming the base film having a refractive index lower than the refractive index of the base 11 and higher than the refractive index of the light reflection reducing film 12, the effect of reducing light reflection can be enhanced. As the base film, a high-refractive-index film of silicon oxide, magnesium fluoride (MgF₂), aluminum oxide (Al₂O₃), tantalum oxide (Ta₂O₅), niobium oxide (Nb₂O₅), or the like can be used. The base film may be a layered film including two or more high-refractive-index films as described above. Further, interposing the base film between the base 11 and the light reflection reducing film 12 such that a coefficient of thermal expansion (CTE) decreases from the base 11 toward the light reflection reducing film 12 allows the adhesion of the first film 12-1 to the base 11 to be improved and the light reflection reducing film 12 formed of the first film 12-1 not to easily be detached from the base 11.

In the present embodiment, the light reflection reducing film 12 is disposed only on the first surface 11a side, which is a light incident surface of the base 11. However, the present disclosure is not limited thereto, and a light reflection reducing film 12 may be further disposed on the second surface 11b side, which is a light exit surface of the base 11. In this case, for example, the light-transmissive member 1 includes: the light-transmissive base 11 having the first surface 11a and the second surface 11b opposite to the first surface 11a, and including, on the second surface, a first region and a second region adjacent to the first region; and the light reflection reducing film 12 having voids and disposed on the second surface 11b of the base 11. The thickness of the light reflection reducing film 12 in the second region is less than the thickness of the light reflection reducing film 12 in the first region, and the light transmittance of the first region is higher than the light transmittance of the second region. By further disposing the light reflection reducing film 12 on the second surface 11b, light reflection on the second surface 11b can be reduced, and the light extraction efficiency of the light-emitting device 100 can be further increased. The first surface may serve as a light exit surface of the base 11, and the light reflection reducing film 12 may be disposed only on the first surface that is the light exit surface. In this case, a light reflection reducing film 12 can be further disposed on the second surface that is a light incident surface of the base 11. The light extraction efficiency of the light-emitting device can be improved in this case as well.

### <Method of Manufacturing Light-Transmissive Member 1>

A method of manufacturing the light-transmissive member 1 according to the embodiment will be described below.

### (Overall Flow of Manufacturing Method)

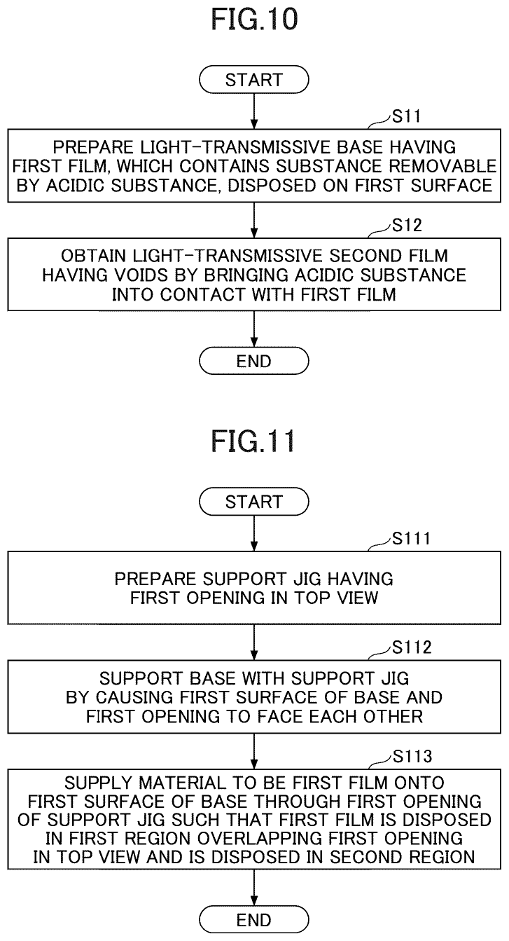

First, FIG. 10 is a flowchart illustrating an example of an overall flow of the method of manufacturing the light-transmissive member 1 according to the embodiment. The method of manufacturing the light-transmissive member 1 includes a step (S11) of providing a light-transmissive base 11 having a first surface 11a, a second surface 11b opposite to the first surface 11a, and a first film 12-1 that contains a substance removable by an acidic substance and is disposed on the first surface 11a. The method of manufacturing the light-transmissive member 1 further includes a step (S12) of obtaining a light-transmissive second film 12-2 having voids by bringing the acidic substance into contact with the first film 12-1. In the method of manufacturing the light-transmissive member 1 according to the embodiment, the first surface 11a of the base 11 includes a first region 121 and a second region 122 adjacent to the first region 121.

### (Details of Step of Providing Base 11 (S11))

FIG. 11 is a flowchart illustrating details of an example of the step (S11) of providing the base 11 in FIG. 10. The step (S11) of providing the base 11 includes a step (S111) of providing a support jig 200 provided with a first opening 240 in a top view, and a step (S112) of supporting the base 11 with the support jig 200 such that the first surface 11a of the base 11 faces the first opening 240 of the support jig 200. The step (S11) of providing the base 11 further includes a step (S113) of supplying a material to be the first film 12-1 onto the first surface 11a of the base 11 through the first opening 240 of the support jig 200 such that the first film 12-1 is disposed in the first region 121 overlapping the first opening 240 in a top view and is disposed in the second region 122 adjacent to the first region 121.

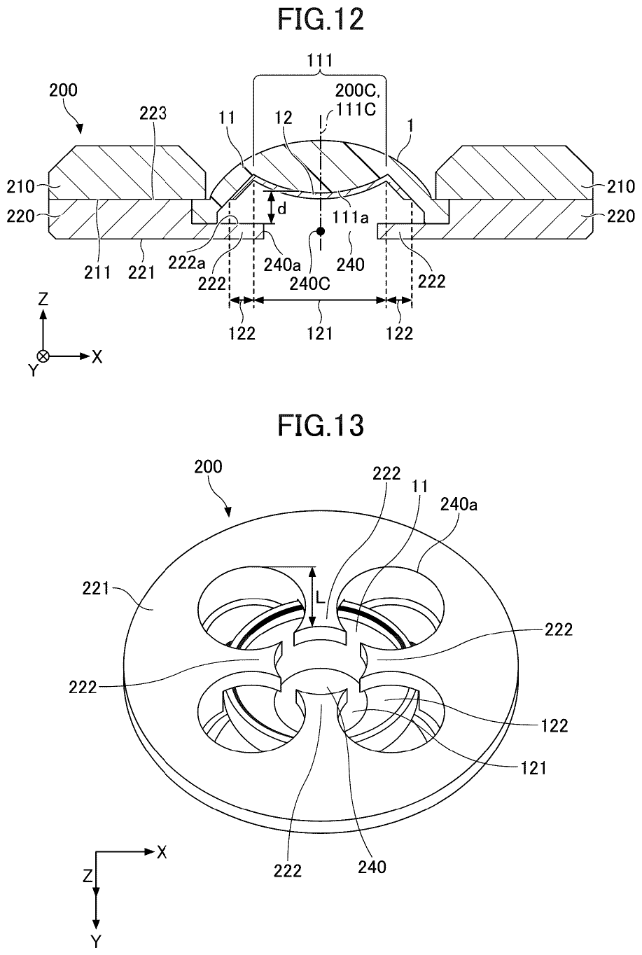

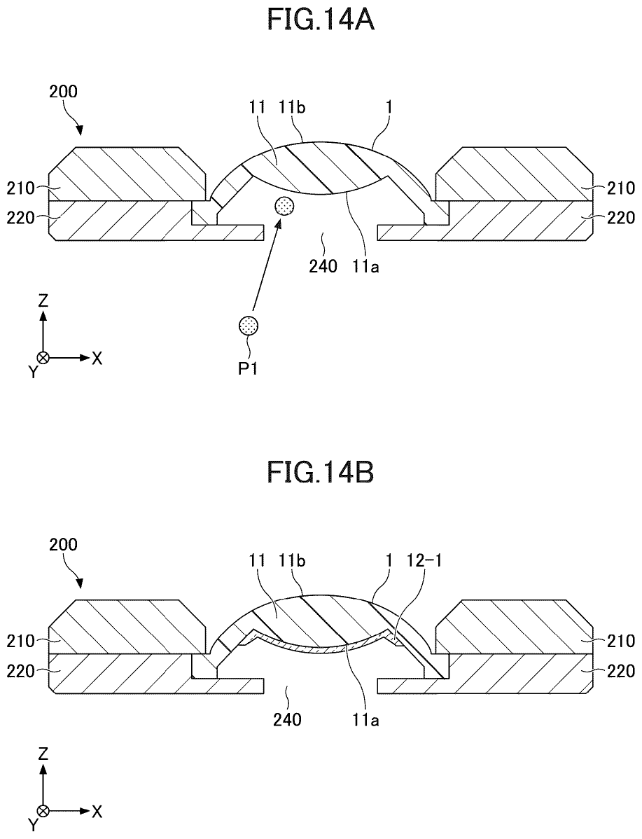

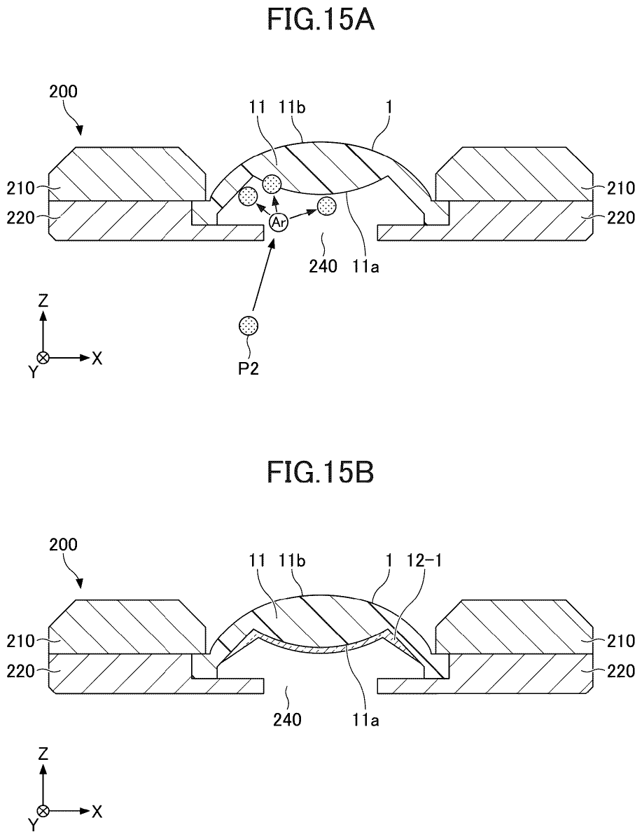

The steps included in the step (S11) of providing the base 11 will be described in detail with reference to FIG. 12, FIG. 13, FIG. 14A, FIG. 14B, FIG. 15A, and FIG. 15B. FIG. 12 is a schematic cross-sectional view illustrating a first example of the support jig 200. FIG. 12 illustrates a cross section of the support jig 200 including a central axis 200C of the support jig 200. The central axis 200C of the support jig 200 is an axis coincide with a center 240C of the first opening 240 of the support jig 200 and extending in a direction normal to the first opening 240. FIG. 13 is a schematic perspective view of the first example of the support jig 200 as viewed from below. FIG. 12 and FIG. 13 illustrate the support jig 200 in a state of supporting the light-transmissive member 1. In FIG. 13, the light reflection reducing film 12 of the light-transmissive member 1 is not depicted. FIG. 14A is a diagram illustrating the behavior of vapor deposition particles P1 in a vapor deposition method. FIG. 14B is a diagram illustrating an example of a film formed by the vapor deposition method. FIG. 15A is a diagram illustrating an example of the behavior of sputtered particles P2 in a sputtering method. FIG. 15B is a diagram illustrating an example of a film formed by the sputtering method.

### (S111: Step of Providing Support Jig 200)

In S111, the support jig 200 having the first opening 240 in a top view is provided. In FIG. 12 and FIG. 13, the support jig 200 includes an upper jig 210 and a lower jig 220. The upper jig 210 is detachably attachable to the lower jig 220. In S111, the support jig 200 in a state in which the upper jig 210 is not attached to the lower jig 220 and before the base 11 is supported is provided. In the example illustrated in FIG. 12 and FIG. 13, the support jig 200 in a state in which the upper jig 210 is attached to the lower jig 220 so as to support the base 11 is depicted.

FIG. 12 and FIG. 13 illustrate a configuration in which the support jig 200 has the one first opening 240 and supports the one base 11. As illustrated in FIG. 13, the outer shape of the support jig 200 in a top view is a substantially circular shape. The outer shape of each of the upper jig 210 and the lower jig 220 in a top view is also a substantially circular shape. In a top view, the opening penetrating the support jig 200 is provided in the center of the support jig 200. The lower jig 220 includes, on a lower surface 221, four protrusions 222 protruding toward the inside of the first opening 240. A protrusion length L of each of the four protrusions 222 illustrated in FIG. 13 protruding inward can be appropriately adjusted according to the thickness or the like of the light reflection reducing film 12 disposed on the base 11. The shape of the first opening 240 in a top view is not limited to a shape including the protrusions 222, and can be appropriately changed according to the thickness or the like of the light reflection reducing film 12 disposed on the base 11. The support jig 200 may support a plurality of bases 11. For example, if the support jig 200 has a plurality of first openings 240, a plurality of bases 11 may be supported by the upper jig 210 and the lower jig 220 so as to correspond to the plurality of first openings 240, respectively.

(S112: Step of Supporting Base 11 with Support Jig 200)

In S112, the support jig 200 supports the base 11 such that the first surface 11a of the base 11 faces the first opening 240 to face. Specifically, first, the base 11 is placed on the surfaces on the +Z side of the protrusions 222, such that the surfaces on the +Z side of the protrusions 222 of the lower jig 220 before the upper jig 210 is attached face the first surface 11a of the base 11 before the light reflection reducing film 12 is disposed. Subsequently, the upper jig 210 is disposed on an upper surface 223 of the lower jig 220, such that the upper surface 223 of the lower jig 220 and a lower surface 211 of the upper jig 210 face each other and the base 11 is sandwiched between a portion of the lower jig 220 and a portion of the upper jig 210 from above and below. Subsequently, the upper jig 210 is fixed to the lower jig 220. As described above, the support jig 200 can support the base 11 by sandwiching the base 11 by a portion of the lower jig 220 and a portion of the upper jig 210 from above and below.

### (S113: Step of Disposing First Film 12-1 in First Region 121 and Second Region 122)

In S113, a material to be the first film 12-1 is supplied onto the first surface 11a of the base 11 through the first opening 240 of the support jig 200 such that the first film 12-1 is disposed in the first region 121 overlapping the first opening 240 in a top view and is disposed in the second region 122 adjacent to the first region 121. A physical vapor deposition method can be used as a method of causing the material to be the first film 12-1 to adhere to the first surface 11a of the base 11. Examples of the physical vapor deposition method include an electron beam vapor deposition method, a resistance heating vapor deposition method, an ion plating method, and a sputtering method. Among them, the electron beam vapor deposition method or the resistance heating vapor deposition method is preferably used, and the electron beam vapor deposition method is more preferably used. The shape of the first opening 240 in a top view is not necessarily similar to the shape of the first region 121 and the second region 122.

The physical vapor deposition method is a method of forming a film composed of an inorganic material on an object in a vacuum environment. In the present embodiment, the first film 12-1 is formed on the first surface 11a of the base 11 by an electron beam vapor deposition method using ion-assisted vapor deposition (hereinafter may be referred to as a vapor deposition method). When the first film 12-1 is formed, the base 11 supported by the support jig 200 is disposed inside a vacuum chamber such that the first surface 11a faces a vapor deposition material. In the present embodiment, the vapor deposition material includes indium oxide and silicon oxide. As the evaporation material, a mixture containing indium oxide in a range of 0.230 mol to 0.270 mol with respect to 1 mol of silicon oxide is used.

Indium oxide used as a raw material of the vapor deposition material is preferably indium oxide (III)(In₂O₃). Indium oxide (III)(In₂O₃) may contain an unavoidable impurity. The content of indium oxide (III)(In₂O₃) in indium oxide used as the raw material is preferably 90% by mass or more, more preferably 95% by mass or more, and even more preferably 99% by mass or more.

Silicon oxide used as a raw material of the vapor deposition material preferably has silicon monoxide (SiO) as a main component. In the present specification, “silicon monoxide (SiO) as a main component” means that the content of silicon monoxide (SiO) in silicon oxide used as the raw material is 50% by mass or more. The content of silicon monoxide (SiO) in silicon oxide used as the raw material is more preferably 80% by mass or more, even more preferably 90% by mass or more, and yet even more preferably 99% by mass or more.

First, a method of forming a first mixed layer 12b1 included in the first film 12-1 will be described. The first mixed layer 12b1 containing silicon dioxide (SiO₂) and indium oxide (I)(In₂O) can be formed on the base 11 by the vapor deposition method in a non-oxidizing atmosphere by using the above-described vapor deposition material. The non-oxidizing atmosphere may be any one or more of an inert atmosphere, a reducing atmosphere, or a vacuum atmosphere. Indium oxide (III)(In₂O₃) contained in the vapor deposition material is dissociated into indium oxide (I)(In₂O), indium (In), and oxide (O) by being heated. Silicon monoxide (SiO) contained in the vapor deposition material preferentially reacts with oxygen (O) to generate silicon dioxide (SiO₂) because a standard free energy for oxidizing silicon monoxide (SiO) is lower than a standard free energy for oxidizing the indium oxide (I)(In₂O). Even in a case where the first film 12-1 is formed by using the vapor deposition material in a non-oxidizing atmosphere, oxygen (O) dissociated from indium oxide (III)(In₂O₃) is preferentially absorbed into silicon monoxide (SiO) to generate silicon dioxide (SiO₂). Thus, silicon monoxide (SiO) hardly remains in the first film 12-1.

In a case where indium (In) is present in vapor dissociated from indium oxide (III)(In₂O₃), because a standard free energy for oxidizing indium (In) to indium oxide (III)(In₂O₃) is lower than a standard free energy for oxidizing silicon monoxide (SiO) to silicon dioxide (SiO₂), such indium (In) may cause indium oxide (III)(In₂O₃), which is generated again by reaction of indium (In) with oxygen, to be contained in the first film 12-1.

The mixture serving as the vapor deposition material is preferably a sintered mixture (sintered body). The vapor deposition material is nearly uniformly vaporized by the vapor deposition method, and the first mixed layer 12b1 in which indium oxide (I)(In₂O), generated by heat decomposition of indium oxide (III)(In₂O₃), and silicon dioxide (SiO₂) are nearly uniformly mixed can be deposited on the base 11.

The atmospheric pressure during the formation of the first mixed layer 12b1 varies depending on the type of physical vapor deposition method to be used. In the case of using the electron beam vapor deposition method, the atmospheric pressure during the formation of the first mixed layer 12b1 on the base 11 is preferably 1.0×10⁻⁴ Pa or more and 5.0×10⁻² Pa or less. The atmospheric pressure during the formation of the first film 12-1 on the base 11 can be controlled by, for example, introducing oxygen into a vapor deposition apparatus.

The temperature of the base 11 during the formation of the first mixed layer 12b1 is preferably 50° C. or more and 150° C. or less, and more preferably 80° C. or more and 120° C. or less. By setting the temperature of the base 11 during the formation of the first mixed layer 12b1 within the above range, the base 11 formed of a material such as a plastic having low heat resistance is less likely to be adversely affected.

As described above, the base 11 is disposed inside the vacuum chamber such that gaseous vapor deposition particles (in the present embodiment, silicon oxide and indium oxide particles) vaporized from the vapor deposition material can pass through the inside of the first opening 240 of the support jig 200 supporting the base 11 within the vacuum chamber. After the base 11 is disposed inside the vacuum chamber, the gaseous vapor deposition particles are caused to collide with the base 11 within the vacuum chamber. After the gaseous vapor deposition particles reach the base 11, the gaseous vapor deposition particles adhere to and are deposited on the first surface 11a of the base 11. The vapor deposition particles are deposited on the first surface 11a of the base 11, and thus the first mixed layer 12b1, which is a vapor deposition film containing indium oxide (I)(In₂O) and silicon dioxide (IV)(SiO₂), can be formed on the first surface 11a of the base 11.

The first film 12-1 may be formed of only the first mixed layer 12b1, but may be a film in which the first mixed layer 12b1 and a silicon dioxide layer 12a are mixed. In the example illustrated in FIG. 6A, the first film 12-1 is formed on the first surface 11a of the base 11. The first film 12-1 is formed by mixing and laminating the first mixed layer 12b1 and the silicon dioxide layer 12a on the first surface 11a of the base 11. In the present embodiment, in addition to the sintered body of the mixture of silicon oxide and indium oxide, a sintered body of silicon monoxide (SiO) is used as a vapor deposition material. First, the first mixed layer 12b1 is formed on the first surface 11a of the base 11 by the electron beam vapor deposition method by using the sintered body of the mixture of silicone oxide and indium oxide as a vapor deposition material. Because silicon oxide and indium oxide do not chemically react with each other on the base 11 and are formed as a mixture, the first mixed layer 12b1 containing silicon oxide and indium oxide is formed as illustrated in FIG. 6A. Next, the silicon dioxide layer 12a is formed on the first mixed layer 12b1, which is formed on the first surface 11a of the base 11, by using the sintered body of silicon oxide as a vapor deposition material. Conditions such as the pressure, the temperature of the base 11, and the like during the formation of the silicon dioxide layer 12a are the same as the conditions during the formation of the first mixed layer 12b1. In this manner, by alternately changing the vapor deposition materials for film disposition, the first film 12-1 in which the first mixed layer 12b1 and the silicon dioxide layer 12a are alternately laminated can be formed as illustrated in FIG. 6A. By alternately laminating the first mixed layer 12b1 and the silicon dioxide layer 12a, gaps and recesses formed during the formation of the first mixed layer 12b1 are filled with the silicon dioxide layer 12a. This can reduce unevenness of the surface of the first film 12-1 and increase the strength of the first film 12-1.

In the electron beam vapor deposition method without using a process gas such as Ar gas, as illustrated in FIG. 14A, vapor deposition particles P1 vaporized from any of the vapor deposition materials directly reach the surface of the base 11 without colliding with particles of the process gas. As described above, because the vapor deposition particles P1 do not collide with the particles of the process gas, the traveling direction of the particles is limited as compared to that of the sputtering method. From another viewpoint, in the vapor deposition method, the directivity of the vapor deposition particles P1 is higher than that of the sputtering method. Therefore, as illustrated in FIG. 14B, the vapor deposition particles P1 tend not to reach a portion of the base 11 hidden by the protrusions 222 of the support jig 200, and the first film 12-1 tends not to be formed on the portion of the base 11 that the vapor deposition particles P1 cannot reach.

In the electron beam vapor deposition method using ion-assisted vapor deposition, ionized particles such as Ar are caused to collide with the vapor deposition particles. The pressure during film formation using ion-assisted vapor deposition is in a low range of 10⁻⁴ Pa or more and 10⁻² Pa or less, and the flow rate of the ionized particles is 1/10 or less of the flow rate of a process gas in the sputtering method. Therefore, an influence of collision between the vapor deposition particles P1 and the ionized particles is negligibly small.

As a method of causing the material to be the first film 12-1 to adhere to the first surface 11a of the base 11, the sputtering method may be used. In the sputtering method illustrated in FIG. 15A, a film deposition process is performed in a state in which a process gas mainly containing Ar gas is filled in the vacuum chamber. Some of sputtered particles P2 sputtered from a target, which is a raw material, reach the base 11 while colliding with Ar atoms. The sputtered particles P2 can travel in various directions by colliding with the Ar atoms. Therefore, as illustrated in FIG. 15B, the sputtered particles P2 can reach a portion of the base 11 hidden by the protrusions 222 of the support jig 200, and the first film 12-1 can be formed on the portion of the base 11.

In the step of providing the base 11 (S11), the light-transmissive base 11 on which the first film 12-1 is disposed can be provided by performing S111 to S113.

### (Details of Step (S12) of Obtaining Second Film 12-2)

In the step of obtaining the second film 12-2, the second film 12-2 having voids are obtained by bringing the first film 12-1 into contact with an acidic solution containing the acidic substance in a range of pH 2.5 or more and pH 3.5 or less.

The first film 12-1 contains indium oxide (I)(In₂O), indium oxide (III)(In₂O₃), and silicon dioxide (IV)(SiO₂). Among the substances contained in the first film 12-1, indium oxide (I)(In₂O) and indium (In) have high solubility to the acidic substance. Thus, indium oxide (I) and indium (In) are preferentially eluted by bringing the first film 12-1 into contact with the acidic substance, and the second film 12-2 having voids that satisfy a desired refractive index and containing silicon dioxide (SiO₂) as a framework can be obtained. Further, among the oxides contained in the first film 12-1, indium oxide (III)(In₂O₃) is also eluted from the first film 12-1 depending on the contact time with the acidic substance, and a part of silicon dioxide (IV)(SiO₂) surrounded by indium oxide (III)(In₂O₃) may also be liberated from the first film 12-1 at the same time when indium oxide (III)(In₂O₃) is eluted from the first film 12-1. A main substance of the second film 12-2 having voids is silicon dioxide (IV)(SiO₂), and the second film 12-2 may contain indium oxide (III)(In₂O₃) that is not eluted.

In the manufacturing method according to the present embodiment, the first film 12-1 containing indium oxide (I)(In₂O) having high solubility to the acidic substance, indium oxide (III)(In₂O₃), and silicon dioxide (IV)(SiO₂) can be formed by using the above-described vapor deposition materials. Then, by bringing the first film 12-1 into contact with the acidic substance, indium oxide (I)(In₂O) having high solubility is eluted first without impairing the durability of the first film 12-1 and the second film 12-2, and the porosity of the second film 12-2 can be increased. By increasing the porosity of the second film 12-2, the second film 12-2 having a low refractive index can be formed. The formed second film 12-2 serves as the light reflection reducing film 12.

As illustrated in FIG. 6B, the second film 12-2 includes a silicon dioxide layer 12a and a second mixed layer 12b2 having voids. The second mixed layer 12b2 contains air and silicon dioxide. The second film 12-2 is obtained by mixing and laminating the silicon dioxide layer 12a and the second mixed layer 12b2 on the first surface 11a of the base 11.

Examples of the acidic substance contained in the acidic solution can include inorganic acids such as hydrochloric acid, sulfuric acid, and nitric acid, and organic acids such as acetic acid, citric acid, and oxalic acid. An acidic solution containing at least one of the above inorganic acids and organic acids can be used. The acidic solution preferably contains oxalic acid and nitric acid. Oxalic acid dissolves indium oxide (I)(In₂O) and indium oxide (III)(In₂O₃) in the first film 12-1, and nitric acid oxidize indium reduced when dissolved by oxalic acid, thereby reducing excessive deposition of indium. The pH value of the acidic solution is in a range of pH 2.5 or more and pH 3.5 or less, and preferably in a range of pH 2.7 or more and pH 3.2 or less. If the pH value of the solution containing the acidic substance falls below 2.5, adhesion between the first film 12-1 and the base 11 would become low, and the first film 12-1 would be detached from base 11 after the first film 12-1 is brought into contact with the solution containing the acidic substance. If the pH value of the acidic solution exceeds 3.5, the dissolution rate of each of indium oxide (I)(In₂O) and indium (In) contained in the first film 12-1 would become low and the time it takes for all indium oxide (I)(In₂O) and indium (In) to be eluted would become long, and thus the manufacturing efficiency would be lowered.

The temperature at which the first film 12-1 is brought into contact with the acidic solution may be room temperature. The room temperature is in a range of 15° C. or more and 28° C. or less, and preferably in a range of 15° C. or more and 25° C. or less. The higher the temperature at which the first film 12-1 is brought into contact with the acidic solution, the more indium oxide (I) (In₂O) and indium (In) can be eluted, which is preferable from a manufacturing point of view because the contact time can be shortened. If the temperature is too high, a solvent in the acidic solution is evaporated, and the pH value is decreased. In such a case, a sealed container or equipment for continuously monitoring and adjusting pH would be required and thus manufacturing costs would be increased. If the temperature is too low, a cooling apparatus would be required and thus manufacturing costs would be increased.

A period of time during which the first film 12-1 is brought into contact with the acidic substance varies according to the contact temperature and the concentration of the acidic substance, and may be a period of time during which the second film 12-2 having a porosity satisfying a desired refractive index is obtained. A period of time during which the first film 12-1 is brought into contact with the acidic substance is preferably 10 seconds or more and more preferably 30 seconds or more, and preferably 36 hours or less and more preferably 25 hours or less to improve the manufacturing efficiency and maintain the durability of the second film 12-2 and the base 11.

Examples of a method of bringing the first film 12-1 into contact with the acidic solution include a method of immersing the base 11 on which the first film 12-1 is formed in the acidic solution and a method of immersing only the first film 12-1 formed on the base 11 in the acidic solution.

The thickness of the first film 12-1 located in the second region 122 is less than the thickness of the first film 12-1 located in the first region 121. In the step of obtaining the second film 12-2, silicon dioxide of the first film 12-1 mainly remains as a framework, and thus the thickness of the second film 12-2 located in the second region 122 is maintained to be less than the thickness of the second film 12-2 in the first region 121.

Because the thickness of the second film 12-2 located in the second region 122 is less than the thickness of the second film 12-2 located in the first region 121, the light transmittance of the first region 121 is higher than the light transmittance of the second region 122. That is, by performing the step of obtaining the second film 12-2, the second film 12-2 can be obtained such that the thickness of the second film 12-2 located in the second region 122 is less than the thickness of the second film 12-2 located in the first region 121 and the light transmittance of the first region 121 is higher than the light transmittance of the second region 122. According to the present embodiment, because the light transmittance of the first region 121 is higher than the light transmittance of the second region 122, the light-transmissive member 1 having good light extraction can be provided.

In the example illustrated in FIG. 12, the base 11 includes the lens 111, and the first surface 11a includes a convex surface 111a including the optical axis 111C. The distance between the convex surface 111a and the support jig 200 increase in a direction away from the optical axis 111C. A distance d in a direction along the optical axis 111C between the convex surface 111a and an upper surface 222a of a corresponding one of the protrusions 222 of the support jig 200 increases in a direction away from the optical axis 111C. Thus, the thickness of the first film 12-1 formed on the convex surface 111a can be changed according to the distance d.

In the example illustrated in FIG. 12 and FIG. 13, the first region 121 is located inward of a contour 240a of the first opening 240 in a top view. Accordingly, the vapor deposition particles can travel without being blocked by the protrusions 222, and thus the thickness of the first film 12-1 formed in the first region 121 can be made uniform regardless of the position.

In the present embodiment, the second region 122 surrounds the entire periphery of the first region 121 in a top view. Accordingly, the second region 122 having a light transmittance lower than that of the first region 121 can be located on the entire outer periphery of the first region 121, and the occurrence of stray light on the entire outer periphery of the first region 121 can be reduced.

In the method of manufacturing the light-transmissive member 1 according to the embodiment, in the step (S11) of providing the base 11, the thickness of the first film 12-1 in the second region 122 is reduced continuously or stepwise in a direction from the first region 121 toward the second region 122. After S11, the light reflection reducing film 12 constituted by the light-transmissive second film 12-2 having voids can be obtained by performing the step (S12) of obtaining the second film 12-2 illustrated in FIG. 10. Thus, the light transmittance of the light-transmissive member 1 decreases continuously or stepwise in a direction from the first region 121 toward the second region 122. Because the light transmittance of the first region 121 is higher than the light transmittance of the second region 122, light extraction can be improved. Further, because the light transmittance decreases continuously or stepwise in a direction from the first region 121 toward the second region 122, stray light, which becomes more pronounced in a direction from the first region 121 toward the second region 122, is not easily transmitted through the light-transmissive member 1. Accordingly, the light-transmissive member 1 can reduce stray light.

The step (S11) of providing the base 11 may include a step of forming, on the first surface 11a of the base 11, a light-transmissive base film having a refractive index lower than the refractive index of the base 11. In the step (S12) of obtaining the second film 12-2, the refractive index of the second film 12-2 is set to be lower than the refractive index of the base film. For example, by laminating the base film and the second film 12-2 in this order on the first surface 11a, the refractive index decreases as the distance from the base 11 increases. In this manner, by forming the base film having a refractive index lower than the refractive index of the base 11 and higher than the refractive index of the second film 12-2, the effect of reducing light reflection can be enhanced.

### (Other Examples of Support Jig 200)

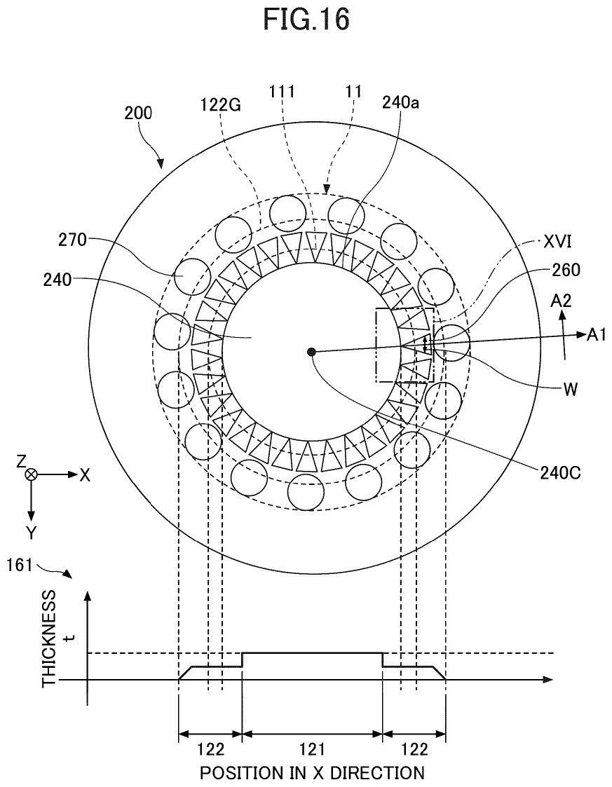

The support jig 200 can have various shapes. Other examples of the support jig 200 will be described with reference to FIG. 16 to FIG. 19.

FIG. 16 is a schematic bottom view illustrating a second example of the support jig 200. In FIG. 16, a graph 161 indicating the thickness t of the light reflection reducing film 12 formed by using the support jig 200 in one cross section passing through the center 240C of the first opening 240 is depicted together with the support jig 200. The support jig 200 and the graph 161 correspond to each other in position in the X direction.

FIG. 16 illustrates a first direction A1 that is parallel to a direction from the center 240C of the first opening 240 toward the outer edge of the first opening 240 in a top view. In the second example illustrated in FIG. 16, the support jig 200 has a second opening 260 that is located outward of the first opening 240 and whose opening width W in a second direction A2 orthogonal to the first direction A1 increases along the first direction A1. This point mainly differs from the first example of the support jig 200 illustrated in FIG. 12 and FIG. 13.

For example, if a light reflection reducing film is formed by using a support jig not having a second opening 260, the number of vapor deposition particles reaching the base 11 is continuously decreased as the distance from the center 240C of the first opening 240 increases in the first direction A1. Thus, the thickness of the light reflection reducing film formed by using the support jig continuously decreases from the center toward the outer edge of the light reflection reducing film.

In view of the above, in the support jig 200 according to the second example, the opening width W, in the second direction A2 orthogonal to the first direction A1, of the second opening 260 increases as the distance from the center 240C of the first opening 240 increases in the first direction A1. Accordingly, the number of vapor deposition particles reaching the base 11 is less likely to be decreased as the distance from the center 240C of the first opening 240 increases in the first direction A1, and can be made substantially constant. By making the number of vapor deposition particles reaching the base 11 substantially constant, as illustrated in the graph 161 of FIG. 16, the thickness t2 of the light reflection reducing film 12 in the second region 122 can be made substantially constant, and then the thickness t2 of the light reflection reducing film 12 in the second region 122 can be changed stepwise with respect to the thickness t1 of the light reflection reducing film 12 in the first region 121. In this manner, by adjusting the opening width of the second opening 260 of the support jig 200, the light reflection reducing film 12 whose thickness t changes stepwise can be easily disposed.

The support jig 200 illustrated in FIG. 16 has a plurality of second openings 260 surrounding the entire periphery of the first opening 240. Accordingly, the light reflection reducing film 12 having the thickness t that changes stepwise can be formed in the second region 122 surrounding the entire periphery of the first region 121.

In a method of manufacturing the light-transmissive member 1 using the support jig 200 illustrated in FIG. 16, the second region outer perimeter 122G of the second region 122 is located outward of the contour of the plurality of second openings 260 in a top view. Thus, the light reflection reducing film 12 having a high light transmittance can be formed in a wide range.

The support jig 200 illustrated in FIG. 16 has a plurality of holes 270 outward of the first opening 240 in a top view. The plurality of holes 270 are provided along the entire periphery of the plurality of second openings 260, which are provided along the entire periphery of the first opening 240. In the step (S12) of obtaining the light-transmissive second film 12-2 having voids, the acidic substance passes through the holes 270 and comes into contact with the first film 12-1 of the base 11 supported by the support jig 200. This makes it easy for bubbles generated by the contact of the acidic substance with the first film 12-1 to escape from the support jig 200 through the holes 270, and thus the light reflection reducing film 12 can be formed with high efficiency.

The holes 270 are not limited to holes each having a substantially circular outer shape in a top view, and each of the holes 270 may have a substantially rectangular shape, a substantially elliptical shape, a substantially polygonal shape, or the like. In addition, the support jig 200 may have holes 270 each having a large area in a top view or may have a plurality of holes 270 arranged at uniform intervals within a range in which the mechanical strength of the support jig 200 is not decreased.

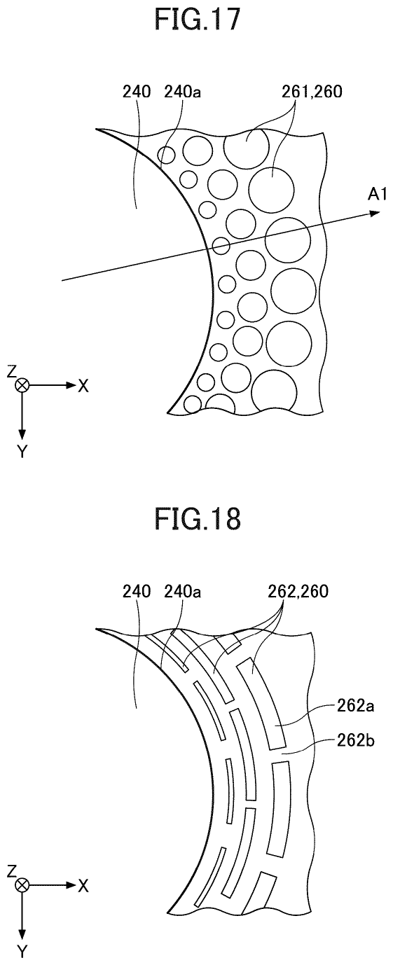

FIG. 17 is a schematic bottom view illustrating a third example of the support jig 200. In the third example of FIG. 17, only a region of the support jig 200 corresponding to a region XVI of FIG. 16 is depicted.

In the third example illustrated in FIG. 17, the second openings 260 include a plurality of circular openings 261. The plurality of circular openings 261 are arranged concentrically around the center 240C of the first opening 240. In the example illustrated in FIG. 17, the centers of circular openings 261 having substantially the same opening size, among the plurality of circular openings 261, are arranged concentrically around the center 240C of the first opening 240. The plurality of circular openings 261 become greater in diameter along the first direction A1. With such second openings 260, the same effects as those of the second example of the support jig 200 can be obtained.

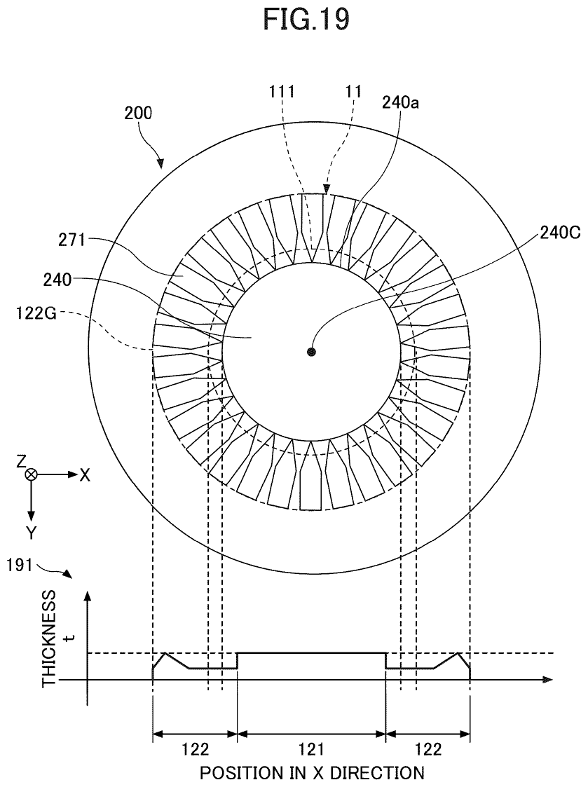

FIG. 18 is a schematic bottom view illustrating a fourth example of the support jig 200. In the fourth example of FIG. 18, only a region of the support jig 200 corresponding to the region XVI of FIG. 16 is depicted.

In the fourth example illustrated in FIG. 18, the second openings 260 include a plurality of arc-like openings 262. Each of the plurality of arc-like openings 262 includes opening portions 262a provided intermittently around the center 240C of the first opening 240 in the circumferential direction. In other words, in each of the plurality of arc-like openings 262, the opening portions 262a and portions 262b that are not opened are alternately arranged in the circumferential direction.

The opening portions 262a become greater in width in the first direction A1 as the distance from the center 240C increases in the first direction A1. Because the opening portions 262a become greater in width in the first direction A1, the opening areas of the plurality of arc-like openings 262 increase along the first direction A1. With such second openings 260, the same effects as those of the second example of the support jig 200 can be obtained. In the plurality of arc-like openings 262, the widths or the lengths of the opening portions 262a in at least one of the first direction A1 or the circumferential direction around the center 240C may increase along the first direction A1.

FIG. 19 is a schematic bottom view illustrating a fifth example of the support jig 200. In FIG. 19, a graph 191 indicating the thickness t of the light reflection reducing film 12 formed by using the support jig 200 in one cross section passing through the center 240C of the first opening 240 is depicted together with the support jig 200. The support jig 200 and the graph 191 correspond to each other in position in the X direction.

In the fifth example of the support jig 200, holes 271 are provided outward of the first opening 240. The holes 271 are holes integrated with the second openings 260. By integrating the holes 270 with the second openings 260, the opening width of each of the holes 271 in the first direction A1 can be increased, and thus the second region 122 can be formed wider and the solution containing the acidic substance and bubbles can more easily pass through the holes 271. When the opening width of each of the holes 271 in the first direction A1 is increased, vapor deposition particles entering the openings of the holes 271 of the support jig 200 in a direction oblique to the +Z side (+Z direction) in the XY plane reach positions of the base 11 far from the center 240C, and thus the thickness t approaches 100% near the outer perimeter of the second region 122. If the thickness t is less than 100%, it can be said that the thickness t is within the range of the second region 122. That is, the thickness t2 of the light reflection reducing film 12 in the second region 122 can be increased in a direction from the first region 121 toward the second region 122 by adjusting the shape of at least one of the first opening 240, the second openings 260, or the holes 270 (holes 271) of the support jig 200. However, the thickness t2 of the light reflection reducing film 12 in the second region 122 is less than the thickness t1 of the light reflection reducing film 12 in the first region 121. The holes 270 may be integrated with the first opening 240, the second openings 260, or both.

### Examples and Comparative Example

Next, light-transmissive members according to specific Examples and a Comparative Example will be described. However, the present disclosure is not limited to the Examples described below. Specifications, an evaluation method, and evaluation results of the light-transmissive members manufactured according to Examples and the Comparative Example are indicated below.

### <Specifications of Light-Transmissive Members>

### (1) Configurations

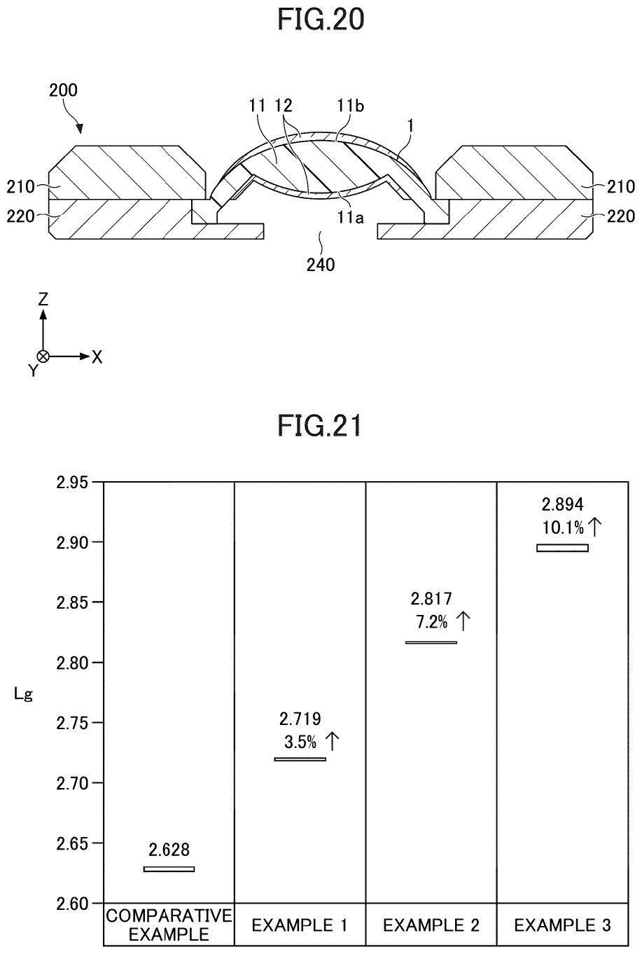

FIG. 20 is a schematic cross-sectional view illustrating a configuration of each of the light-transmissive members according to Examples and the Comparative Example. In each of the light-transmissive members according to Examples and the Comparative Example, a base 11 included a lens 111 and a support 112.
Example 1: A base film and a light reflection reducing film 12 were disposed in this order only on the second surface 11b of the base 11.
Example 2: The base film and the light reflection reducing film 12 were disposed in this order only on the first surface 11a of the base 11.
Example 3: The base film and the light reflection reducing film 12 were disposed in this order on both the first surface 11a and the second surface 11b of the base 11.
Comparative Example: a configuration including only the base 11 and not including a base film and a light reflection reducing film 12 was adopted.

### (2) Material

Polycarbonate was used for the base 11. A silicon dioxide layer was used for the base film. The light reflection reducing film 12 composed of a silicon dioxide layer 12a having voids was used.

### (3) Base Film

The silicon dioxide layer serving as the base film was formed by the sputtering method. The maximum thickness of the base film was 910 Å.

### (4) Light Reflection Reducing Film

The support jig illustrated in FIG. 13 was used to form the light reflection reducing film 12 by adjusting the protrusion length L of each of the four protrusions 222 protruding toward the inside of the first opening 240. A first film 12-1 was formed by alternately laminating a first mixed layer 12b1 and a silicon dioxide layer 12a. The first mixed layer 12b1 and the silicon dioxide layer 12a of the first film 12-1 were formed by the electron beam vapor deposition method using ion-assisted deposition in an Ar gas atmosphere at 0.01 Pa or less and at room temperature. The base 11 on which the first film 12-1 was formed was immersed in a mixed solution of oxalic acid and nitric acid of pH 3, which serves as an acidic solution containing an acidic substance, at 25° C. (room temperature) for one hour. As a result, the base 11 on which a second film 12-2 (light reflection reducing film 12) was formed was obtained. The maximum thickness of the light reflection reducing film 12 was 1,200 Å, and the thickness of the light reflection reducing film 12 in the second region 122 was continuously changed in a direction from the first region 121 toward the second region 122.

### <Evaluation Method>

A light source including nine light-emitting parts (light-emitting surfaces) arranged two-dimensionally was used. The light-emitting parts were LEDs. The illuminance of light emitted from the light source and transmitted through each of the light-transmissive members according to the Comparative Example, Example 1, Example 2, and Example 3 was measured by an illuminance meter. The illuminance was evaluated by using an illuminance characteristic value Lg calculated by the following formula. The unit of a measured value of illuminance is lux. In the following formula, “illuminance of light from light source only” means illuminance measured by the illuminance meter when light from the light source is directly incident on the illuminance meter without being transmitted through each of the light-transmissive members.

$$Lg = ( illuminance of light transmitted through light - transmissive member ) / \\ ( illuminance of light from light source only )$$

### <Evaluation Results>

FIG. 21 is a diagram illustrating measurement results of the illuminance of the light-transmissive members according to Examples and the Comparative Example. As illustrated in FIG. 21, in Example 1, the illuminance characteristic value Lg was improved by 3.5% as compared to that of the Comparative Example. In Example 2, the illuminance characteristic value Lg was improved by 7.2% as compared to that of the Comparative Example. In Example 3, the illuminance characteristic value Lg was improved by 10.1% as compared to that of the Comparative Example.

From the above results, it can be seen that the illuminance characteristic values in Example 1 to Example 3 were improved as compared to that of the Comparative Example.

Although embodiments have been described in detail above, the above-described embodiments are non-limiting examples, and various modifications and substitutions can be made to the above-described embodiments without departing from the scope described in the claims.

The numbers such as ordinal numbers and quantities used in the description of the embodiments are all exemplified to specifically describe the technique of the present disclosure, and the present disclosure is not limited to the exemplified numbers. In addition, the connection relationship between the components is illustrated for specifically describing the technique of the present disclosure, and the connection relationship for implementing the functions of the present disclosure is not limited thereto.

The light-emitting device according to the present disclosure has good light extraction, and thus can be suitably used for a lighting, a lighting device, a camera flash, a vehicle headlight, and the like. Further, the light-transmissive member according to the present disclosure can be suitably used for a lens or the like of the light-emitting device used in any of the above applications. The manufacturing method according to the present disclosure can be suitably used for manufacturing the light-transmissive member of the light-emitting device used in any of the above applications. However, the light-transmissive member, the light-emitting device, the method of manufacturing the light-transmissive member according to the present disclosure are not limited to these applications.

According to one embodiment of the present disclosure, a light-transmissive member having good light extraction, a light-emitting device, and a method of manufacturing a light-transmissive member can be provided.

What is claimed is:

1. A method of manufacturing a light-transmissive member, the method comprising:
providing a member comprising:
a base having light transmissivity, the base having a first surface, a second surface opposite to the first surface, and
a first film disposed on the first surface, the first film containing a substance removable by an acidic substance; and
obtaining a light-transmissive second film having voids by bringing the first film into contact with the acidic substance, wherein:
the first surface of the base comprises a first region and a second region adjacent to the first region, wherein:
a light transmittance of the first region is higher than a light transmittance of the second region, and
a thickness of the second film located in the second region is less than a thickness of the second film located in the first region.

2. The method of manufacturing the light-transmissive member according to claim 1, wherein:
the providing of the member comprises:
providing a support jig having a first opening in a top view,
supporting the base with the support jig such that the first surface of the base faces the first opening of the support jig, and
supplying a material to be the first film onto the first surface of the base through the first opening of the support jig such that the first film is disposed in the first region overlapping the first opening in the top view and is disposed in the second region adjacent to the first region.

3. The method of manufacturing the light-transmissive member according to claim 2, wherein the base comprises a lens, the first surface comprises a convex surface comprising an optical axis, and a distance between the convex surface and the support jig increases in a direction away from the optical axis.

4. The method of manufacturing the light-transmissive member according to claim 2, wherein the first region is located inward of a contour of the first opening in the top view.

5. The method of manufacturing the light-transmissive member according to claim 1, wherein the second region surrounds an entire periphery of the first region in a top view.

6. The method of manufacturing the light-transmissive member according to claim 1, wherein, in the providing of the member, a thickness of the first film in the second region decreases continuously or stepwise in a direction from the first region toward the second region.

7. The method of manufacturing the light-transmissive member according to claim 1, wherein:
the providing of the member comprises forming, on the first surface of the base, a light-transmissive base film having a refractive index lower than a refractive index of the base, and
in the obtaining of the second film, a refractive index of the second film is lower than the refractive index of the base film.

8. The method of manufacturing the light-transmissive member according to claim 2, wherein:
a first direction is parallel to a direction from a center of the first opening toward an outer edge of the first opening and a second direction is orthogonal to the first direction, and
the support jig has a second opening that is located outward of the first opening in the top view and a width of the second opening in the second direction increases along the first direction.

9. The method of manufacturing the light-transmissive member according to claim 8, wherein the second opening of the support jig comprises a plurality of second openings surrounding an entire periphery of the first opening.

10. The method of manufacturing the light-transmissive member according to claim 8, wherein an outer perimeter of the second region is located outward of a contour of the second opening in the top view.

11. The method of manufacturing the light-transmissive member according to claim 2, wherein:
the support jig has a hole located outward of the first opening in the top view, and
in the obtaining of the second film having the voids, the acidic substance passes through the hole and contacts the first film of the member supported by the support jig.

12. The method of manufacturing the light-transmissive member according to claim 8, wherein:
the support jig has a hole located outward of the first opening in the top view, and
the hole is integrated with at least one of the first opening or the second opening.

13. A light-transmissive member comprising:
a base having light transmissivity comprising a first surface and a second surface opposite to the first surface, and comprising, on the first surface, a first region and a second region adjacent to the first region; and
a light reflection reducing film disposed on the first surface of the base, composed of an inorganic material, and having voids, wherein:
a light transmittance of the first region is higher than a light transmittance of the second region, and a thickness of the light reflection reducing film in the second region is less than a thickness of the light reflection reducing film in the first region.

14. The light-transmissive member according to claim 13, wherein the thickness of the light reflection reducing film in the second region decreases continuously or stepwise in a direction from the first region toward the second region.

15. The light-transmissive member according to claim 13, further comprising:
a light-transmissive base film having a refractive index lower than a refractive index of the base and higher than a refractive index of the light reflection reducing film, the light-transmissive base film being disposed between the base and the light reflection reducing film.

16. A light-emitting device comprising:
the light-transmissive member of claim 13; and
a light source that faces the first surface of the light-transmissive member, wherein:
the light source has a light-emitting surface, and
the first region overlaps the light-emitting surface in a top view.

17. The light-emitting device according to claim 16, wherein a difference between the thickness of the light reflection reducing film in the first region and the thickness of the light reflection reducing film in the second region is 5% or more of the thickness of the light reflection reducing film in the first region.

18. The light-emitting device according to claim 16, wherein a maximum thickness of the light reflection reducing film in the first region is 500 Å or more and 2,000 Å or less.

19. The light-emitting device according to claim 16, further comprising:
an additional light reflection reducing film disposed on the second surface of the base.

20. The light-emitting device according to claim 16, wherein:
the base comprises a lens, and
the first region is located at a position overlapping an optical axis of the lens in the top view.
